(19) United States
(12) Patent Application Publication
(10) Pub. No.: US 2025/0266662 A1
(43) Pub. Date: Aug. 21, 2025

(54) SURFACE EMITTING LASER

(71) Applicant: SONY GROUP CORPORATION, Tokyo (JP)

(72) Inventors: Tatsuya MATOU, Tokyo (JP); Hideki WATANABE, Tokyo (JP); Rintaro KODA, Tokyo (JP)

(21) Appl. No.: 18/293,048

(22) PCT Filed: Feb. 18, 2022
(86) PCT No.: PCT/JP2022/006538

§ 371 Date: Aug. 1, 2024

(30) Foreign Application Priority Data
Sep. 13, 2021 (JP) 2021-148508

(51) Int. Cl. H01S 5/183; H01S 5/227

(52) U.S. Cl. CPC H01S 5/18311; H01S 5/1835; H01S 5/18361; H01S 5/227

(57) ABSTRACT

A surface emitting laser having an isotropically selectively oxidized oxidation confinement layer is provided.

The surface emitting laser according to the present technology includes: a first multilayer film reflector; a second multilayer film reflector; an active layer disposed between the first and second multilayer film reflectors; and an oxidation confinement layer disposed between the second multilayer film reflector and the resonator and having a non-oxidized region and an oxidized region, in which the oxidation confinement layer includes an oxidation adjustment structure. According to the surface emitting laser according to the present technology, it is possible to provide a surface emitting laser having an isotropically selectively oxidized oxidation confinement layer.

### TECHNICAL FIELD

The technology according to the present disclosure (hereinafter also referred to as “the present technology”) relates to a surface emitting laser.

### BACKGROUND ART

In realizing a current confinement structure using an oxidation confinement layer, it is difficult to control the current confinement diameter to a constant value due to variations in oxidation length.

Conventionally, a semiconductor laser having a protruding or recessed step pattern has been devised in order to realize selective oxidation of an oxidation confinement layer with good controllability (see, for example, Patent Document 1). By forming the oxidation confinement layer on the step pattern, the oxidation confinement layer can be thinned or cut off at the step boundary portion, and as a result, selective oxidation with good controllability can be performed.

### CITATION LIST

### Patent Document

Patent Document 1: Japanese Patent Application Laid-Open No. 2002-151791

### SUMMARY OF THE INVENTION

### Problems to be Solved by the Invention

However, when a conventional semiconductor laser having a step shape is produced, in a process, the longitudinal cross section of the step pattern has a slope whose boundary portion is not an ideal rectangle, and the slope of the step pattern having a surface perpendicular to a specific direction in the horizontal cross section is configured such that a {111} A plane alone or a plurality of surfaces including the {111} A plane, to which As atoms are easily adsorbed, alternately appear. The specific direction is an arbitrary crystal orientation within an angle range of ±22.5° from the direction (see FIG. 53) in a case where the longitudinal cross section of the step pattern has a forward taper, and the [0-11] direction in a case where the longitudinal cross section has a reverse taper, in a plane including the direction and the direction. In this case, the step slope is at least partially configured by the {111} A plane. At this time, the oxidation confinement layer formed on the slope of the step boundary portion tends to be thickened rather than thinned, and as a result, there is room for improvement in that it is difficult to selectively oxidize only the oxidized region isotropically.

Therefore, a main object of the present technology is to provide a surface emitting laser having an isotropically selectively oxidized oxidation confinement layer.

### Solutions to Problems

The present technology provides a surface emitting laser including:
a first multilayer film reflector; a second multilayer film reflector;
an active layer disposed between the first and second multilayer film reflectors; and
an oxidation confinement layer disposed between the second multilayer film reflector and the active layer and having a non-oxidized region and an oxidized region, in which the oxidation confinement layer includes an oxidation adjustment structure.

The semiconductor device may further a semiconductor layer protruding from a side of the active layer to a side of the second multilayer film reflector or recessed from the side of the second multilayer film reflector to the side of the active layer, in which the oxidation confinement layer covers the semiconductor layer from the side of the second multilayer film reflector, and the oxidation adjustment structure includes an oxidation progression suppressing portion.

In addition, the oxidation adjustment structure may include a route-around portion.

The surface emitting laser according to the present technology may have, for example, any one of the following configurations (1) to (5) or a combination thereof.
(1) The semiconductor layer has a forward tapered longitudinal cross section, and does not have a plane perpendicular to any crystal orientation within an angle range of ±22.5° from the direction in a plane including the direction and the direction. This prevents the {111} A plane from appearing on the slope of the step boundary portion.
(2) The semiconductor layer has a reverse tapered longitudinal cross section, and does not have a plane perpendicular to any crystal orientation within an angle range of ±22.5° from the [0-11] direction in a plane including the direction and the direction.

This prevents the {111} A plane from appearing on the slope of the step boundary portion.

(3) The semiconductor layer has a structure in which a longitudinal cross section has both a forward tapered shape and a reverse tapered shape. A {111} A plane may appear on the slope of the step located in the specific direction. However, since the {111} A plane appears only on one of the forward tapered surface and the reverse tapered surface and does not appear on the other surface, as a result, the oxidation confinement layer is thinned or cut off at the step boundary portion regardless of the in-plane direction.

(4) The semiconductor layer has an eaves structure in a longitudinal cross section. Since the route-around portion of the oxidized region is generated, it is possible to realize a structure that does not affect the current confinement diameter while allowing variation in oxidation length.

(5) A groove provided from the front surface side on the second multilayer film reflector side is provided in the vicinity of the semiconductor layer. In this case, a structure similar to (4) can be realized.

Note that, in a case where the structure of (1) or (2) is provided alone, the horizontal cross section needs to be a polygon or the like instead of a circle in order to prevent the {111} A plane from appearing.

The oxidation progression suppressing portion may have a thin film portion and/or a cutoff portion.

The oxidation progression suppressing portion May exist corresponding to the entire circumference of the non-oxidized region.

The oxidation progression suppressing portion may be provided on at least a part of a side surface of the semiconductor layer.

The semiconductor layer may not have a rectangular longitudinal cross section.

The semiconductor layer may not have a {111} A plane on a surface thereof.

The semiconductor layer may have a polygonal horizontal cross section.

The oxidation confinement layer may not have a thick film portion.

A boundary between the non-oxidized region and the oxidized region may exist in the oxidation progression suppressing portion.

The oxidation confinement layer may have a thin film portion and a thick film portion in a predetermined longitudinal cross section.

The oxidation confinement layer may have a boundary between the non-oxidized region and the oxidized region at a position corresponding to a boundary between the forward tapered shape and the reverse tapered shape of the semiconductor layer.

A boundary between the non-oxidized region and the oxidized region may exist in the route-around portion.

The surface emitting laser may further include a semiconductor layer protruding from a side of the active layer to a side of the second multilayer film reflector or recessed from the side of the second multilayer film reflector to the side of the active layer, in which the oxidation confinement layer covers the semiconductor layer from the side of the second multilayer film reflector, and at least a part of the route-around portion extends along the semiconductor layer.

The surface emitting laser may further include a semiconductor layer disposed between the second multilayer film reflector and the active layer, in which a groove may be provided on a surface on the side of the second multilayer film reflector, and at least a part of the route-around portion may extend along the groove.

### BRIEF DESCRIPTION OF DRAWINGS

FIG. 1A is a cross-sectional view of a surface emitting laser according to Example 1 of a first embodiment of the present technology. FIG. 1B is a plan view of a surface emitting laser according to Example 1 of the first embodiment of the present technology.

FIG. 2 is a diagram illustrating a relationship between a plan view shape and a crystal orientation of a semiconductor layer of the surface emitting laser illustrated in FIG. 1A.

FIG. 3 is a flowchart for explaining a method for manufacturing the surface emitting laser illustrated in FIG. 1A.

FIG. 4 is a cross-sectional view for each step of the method for manufacturing the surface emitting laser illustrated in FIG. 1A.

FIG. 5A is a cross-sectional view for each step of the method for manufacturing the surface emitting laser illustrated in FIG. 1A. FIG. 5B is a plan view corresponding to FIG. 5A.

FIGS. 6A and 6B are cross-sectional views for each step of the method for manufacturing the surface emitting laser illustrated in FIG. 1A. FIG. 6C is a plan view corresponding to FIG. 6B.

FIGS. 7A and 7B are cross-sectional views for each step of the method for manufacturing the surface emitting laser illustrated in FIG. 1A.

FIGS. 8A and 8B are cross-sectional views for each step of the method for manufacturing the surface emitting laser illustrated in FIG. 1A.

FIGS. 9A and 9B are cross-sectional views for each step of the method for manufacturing the surface emitting laser illustrated in FIG. 1A.

FIGS. 10A and 10B are cross-sectional views for each process of the method for manufacturing the surface emitting laser illustrated in FIG. 1A, respectively.

FIGS. 11A and 11B are cross-sectional views for each process of the method for manufacturing the surface emitting laser illustrated in FIG. 1A, respectively.

FIG. 12 is a cross-sectional view of a surface emitting laser according to Example 2 of the first embodiment of the present technology.

FIG. 13 is a diagram illustrating a relationship between a plan view shape and a crystal orientation of a semiconductor layer of the surface emitting laser illustrated in FIG. 12.

FIG. 14 is a flowchart for explaining a method for manufacturing the surface emitting laser illustrated in FIG. 12.

FIGS. 15A and 15B are cross-sectional views for each process of the method for manufacturing the surface emitting laser illustrated in FIG. 12, respectively.

FIGS. 16A and 16B are cross-sectional views for each process of the method for manufacturing the surface emitting laser illustrated in FIG. 12, respectively.

FIGS. 17A and 17B are cross-sectional views for each process of the method for manufacturing the surface emitting laser illustrated in FIG. 12, respectively.

FIGS. 18A and 18B are cross-sectional views for each process of the method for manufacturing the surface emitting laser illustrated in FIG. 12, respectively.

FIGS. 19A and 19B are cross-sectional views for each process of the method for manufacturing the surface emitting laser illustrated in FIG. 12, respectively.

FIGS. 20A and 20B are cross-sectional views for each process of the method for manufacturing the surface emitting laser illustrated in FIG. 12, respectively.

FIGS. 21A and 21B are cross-sectional views for each process of the method for manufacturing the surface emitting laser illustrated in FIG. 12, respectively.

FIG. 22 is a cross-sectional view (part 1) of a surface emitting laser according to a second embodiment of the present technology.

FIG. 23 is a cross-sectional view (part 2) of a surface emitting laser according to a second embodiment of the present technology.

FIGS. 24A and 24B are cross-sectional views for each step of the method for manufacturing the surface emitting laser illustrated in FIGS. 22 and 23, respectively.

FIG. 25 is a cross-sectional view of a surface emitting laser according to Example 1 of the third embodiment of the present technology.

FIGS. 26A and 26B are cross-sectional views for each process of the method for manufacturing the surface emitting laser illustrated in FIG. 25, respectively.

FIG. 27 is a cross-sectional view of a surface emitting laser according to Example 2 of the third embodiment of the present technology.

FIGS. 28A and 28B are cross-sectional views for each process of the method for manufacturing the surface emitting laser illustrated in FIG. 27, respectively.

FIGS. 29A and 29B are cross-sectional views for each process of the method for manufacturing the surface emitting laser illustrated in FIG. 27, respectively.

FIG. 30 is a cross-sectional view of a surface emitting laser according to Modification 1 of the first embodiment of the present technology.

FIG. 31 is a cross-sectional view of a surface emitting laser according to Modification 2 of the first embodiment of the present technology.

FIG. 32 is a cross-sectional view of a surface emitting laser according to Modification 3 of the first embodiment of the present technology.

FIG. 33 is a cross-sectional view of a surface emitting laser according to Modification 4 of the first embodiment of the present technology.

FIG. 34 is a flowchart for explaining a method for manufacturing the surface emitting laser illustrated in FIG. 33.

FIGS. 35A and 35B are cross-sectional views for each process of the method for manufacturing the surface emitting laser illustrated in FIG. 33, respectively.

FIGS. 36A and 36B are cross-sectional views for each process of the method for manufacturing the surface emitting laser illustrated in FIG. 33, respectively.

FIGS. 37A and 37B are cross-sectional views for each process of the method for manufacturing the surface emitting laser illustrated in FIG. 33, respectively.

FIGS. 38A and 38B are cross-sectional views for each process of the method for manufacturing the surface emitting laser illustrated in FIG. 33, respectively.

FIGS. 39A and 39B are cross-sectional views for each process of the method for manufacturing the surface emitting laser illustrated in FIG. 33, respectively.

FIGS. 40A and 40B are cross-sectional views for each process of the method for manufacturing the surface emitting laser illustrated in FIG. 33, respectively.

FIGS. 41A and 41B are cross-sectional views for each process of the method for manufacturing the surface emitting laser illustrated in FIG. 33, respectively.

FIG. 42 is a cross-sectional view of a surface emitting laser according to Modification 5 of the first embodiment of the present technology.

FIG. 43 is a cross-sectional view of a surface emitting laser according to Modification 6 of the first embodiment of the present technology.

FIG. 44 is a cross-sectional view of a surface emitting laser according to Modification 7 of the first embodiment of the present technology.

FIG. 45 is a cross-sectional view of a surface emitting laser according to Modification 8 of the first embodiment of the present technology.

FIGS. 46A and 46B are cross-sectional views (Part 1 and Part 2) of a surface emitting laser according to a modification of the second embodiment of the present technology, respectively.

FIG. 47 is a cross-sectional view of a surface emitting laser according to Modification 1 of the third embodiment of the present technology.

FIG. 48 is a cross-sectional view of a surface emitting laser according to Modification 2 of the third embodiment of the present technology.

FIG. 49 is a cross-sectional view of a surface emitting laser according to Modification 3 of the third embodiment of the present technology.

FIG. 50 is a cross-sectional view of a surface emitting laser according to Modification 4 of the third embodiment of the present technology.

FIG. 51 is a cross-sectional view of a surface emitting laser according to Modification 5 of the third embodiment of the present technology.

FIG. 52 is a cross-sectional view of a surface emitting laser according to Modification 6 of the third embodiment of the present technology.

FIG. 53 is a diagram for explaining a problem of the present technology.

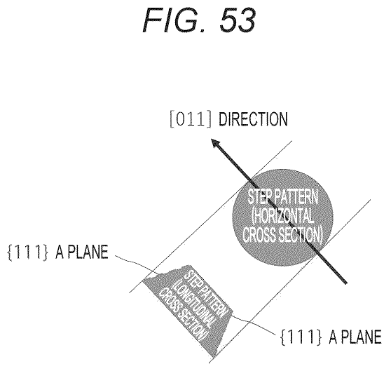

FIG. 54 is a plan view of an oxidation confinement layer of a surface emitting laser of a comparative example.

FIG. 55 is a diagram illustrating an application example of the surface emitting laser according to Example 1 of the first embodiment of the present technology to the distance measuring device.

FIG. 56 is a block diagram illustrating an example of a schematic configuration of a vehicle control system.

FIG. 57 is an explanatory diagram illustrating an example of installation positions of distance measuring devices.

### MODE FOR CARRYING OUT THE INVENTION

Hereinafter, preferred embodiments of the present technology will be described in detail with reference to the accompanying drawings. Note that, in the present specification and drawings, components having substantially the same functional configuration are denoted by the same reference signs, and redundant description is omitted. The embodiments described below illustrate representative embodiments of the present technology, and the scope of the present technology is not narrowly interpreted by these embodiments. In the present specification, even in a case where it is described that a surface emitting laser according to the present technology exhibits a plurality of effects, it suffices that the surface emitting laser according to the present technology exhibits at least one effect. The effects described herein are merely examples and are not limited, and other effects may be provided.

Furthermore, the description will be given in the following order.
1. Introduction
2. Surface Emitting Laser According to Example 1 of First Embodiment of Present Technology
3. Surface Emitting Laser According to Example 2 of First Embodiment of Present Technology
4. Surface Emitting Laser According to Second Embodiment of Present Technology
5. Surface Emitting Laser According to Example 1 of Third Embodiment of Present Technology
6. Surface Emitting Laser According to Example 2 of Third Embodiment of Present Technology
7. Surface Emitting Laser According to Modification 1 of First Embodiment of Present Technology
8. Surface Emitting Laser According to Modification 2 of First Embodiment of Present Technology
9. Surface Emitting Laser According to Modification 3 of First Embodiment of Present Technology
10. Surface Emitting Laser According to Modification 4 of First Embodiment of Present Technology
11. Surface Emitting Laser According to Modification 5 of First Embodiment of Present Technology
12. Surface Emitting Laser According to Modification 6 of First Embodiment of Present Technology
13. Surface Emitting Laser According to Modification 7 of First Embodiment of Present Technology
14. Surface Emitting Laser According to Modification 8 of First Embodiment of Present Technology
15. Surface Emitting Laser According to Modification of Second Embodiment of Present Technology
16. Surface Emitting Laser According to Modification 1 of Third Embodiment of Present Technology
17. Surface Emitting Laser According to Modification 2 of Third Embodiment of Present Technology
18. Surface Emitting Laser According to Modification 3 of Third Embodiment of Present Technology
19. Surface Emitting Laser According to Modification 4 of Third Embodiment of Present Technology
20. Surface Emitting Laser According to Modification 5 of Third Embodiment of Present Technology
21. Surface Emitting Laser According to Modification 6 of Third Embodiment of Present Technology
22. Other Modifications of Present Technology
23. Application Example to Electronic Device
24. Example in Which Surface Emitting Laser Is Applied to Distance Measuring Device
25. Example in Which Distance Measuring Device Is Mounted on Moving Body

### <1. Introduction>

Vertical cavity surface emitting lasers (VCSEL) having an oxidation confinement layer are widely used. The oxidation confinement layer has an oxidized region in a region not corresponding to the emission port. There is a method of epitaxially growing the oxidation confinement layer on the step pattern in order to generate the oxidation confinement layer. In this method, since the oxidation confinement layer is easily thinned and/or cut off at the step boundary portion, oxidation is easily stopped at the step boundary portion during the oxidation step, and selective oxidation with good controllability is easily realized.

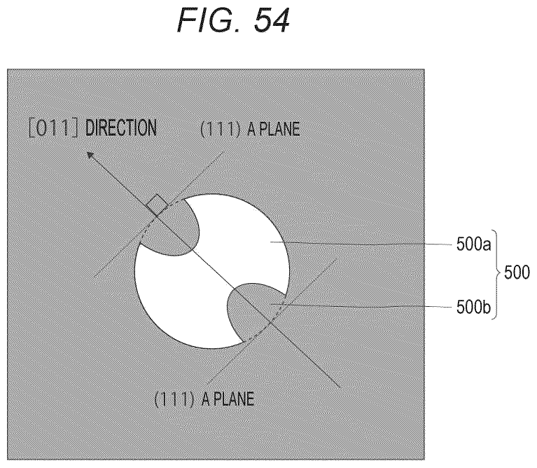

However, in the surface emitting laser of the comparative example adopting this method, the oxidation confinement layer tends to be thickened on the {111} A plane exposed on the slope of the step boundary portion facing the specific direction, and the oxidation rate becomes faster accordingly, so that isotropic selective oxidation becomes difficult (see FIG. 54). The surface emitting laser of this comparative example has a step pattern having a circular shape in plan view and a forward tapered cross section, and the plan view shapes of the non-oxidized region 500a and the oxidized region 500b tend to be anisotropic in the oxidation confinement layer 500 formed on the step pattern. In this case, there is a concern about an influence on laser characteristics. Note that the {111} A plane exists on the slope of the step boundary portion when viewed in the cross section in the direction (hereinafter also referred to as “reverse mesa direction”) as illustrated in FIG. 54 in the forward tapered step, and exists on the slope of the step boundary portion when viewed in the cross section in the [01-1] direction (hereinafter also referred to as “forward mesa direction”) in the reverse tapered step.

In the surface emitting laser of the comparative example, since the plan view shapes of the non-oxidized region 500a and the oxidized region 500b of the oxidation confinement layer 500 can be anisotropic, there is room for improvement in the improvement in the feasibility of isotropic selective oxidation.

Therefore, the inventors have developed a surface emitting laser according to the present technology as a surface emitting laser capable of making the plan view shapes of the oxidized region and the non-oxidized region of the oxidation confinement layer isotropic.

Hereinafter, some embodiments of a surface emitting laser according to the present technology will be described with reference to the drawings. In the following description, for the sake of convenience, the upper side in each cross-sectional view will be described as upper, and the lower side will be described as lower.

### <2. Surface Emitting Laser According to Example 1 of First Embodiment of Present Technology>

### <<Configuration of Surface Emitting Laser>>

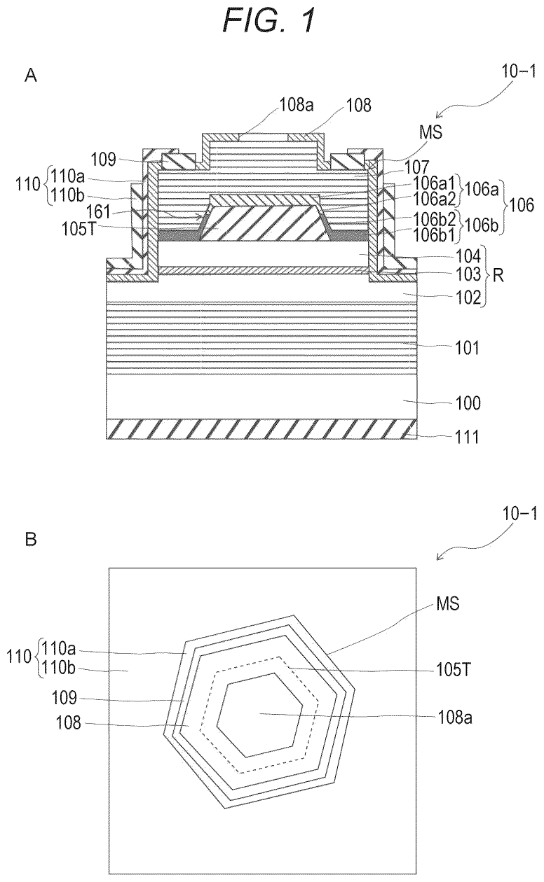

Hereinafter, a configuration of a surface emitting laser according to Example 1 of the first embodiment of the present technology will be described. FIG. 1A is a cross-sectional view of a surface emitting laser 10-1 according to Example 1 of the first embodiment of the present technology. FIG. 1B is a plan view of the surface emitting laser 10-1 according to Example 1 of the first embodiment of the present technology.

As an example, as illustrated in FIG. 1A, the surface emitting laser 10-1 according to Example 1 of the first embodiment includes a first multilayer film reflector 101, a second multilayer film reflector 107, a resonator configuration portion R that is disposed between the first and second multilayer film reflectors 101 and 107 and constitutes a part of a resonator including an active layer 103, a semiconductor layer 105T protruding from the active layer 103 side to the second multilayer film reflector 107 side, and an oxidation confinement layer 106 that is disposed between the second multilayer film reflector 107 and the active layer 103 and covers the semiconductor layer 105T from the second multilayer film reflector 107 side. A resonator is configured by including the first and second multilayer film reflectors 101 and 107 and the resonator configuration portion R.

In the surface emitting laser 10-1, as an example, the first multilayer film reflector 101, the resonator configuration portion R, the semiconductor layer 105T, the oxidation confinement layer 106, and the second multilayer film reflector 107 are laminated in this order on one surface (front surface) of a substrate 100. A cathode electrode 111 is provided on the other surface (back surface) of the substrate 100.

In the surface emitting laser 10-1, as an example, a mesa structure MS is configured including a part (upper portion) of the resonator configuration portion R, the semiconductor layer 105T, the oxidation confinement layer 106, and the second multilayer film reflector 107. The top portion of the mesa structure MS has a step where the central portion is higher than the peripheral portion.

As an example, the mesa structure MS has a polygonal shape (for example, a regular hexagon) as the plan view shape (see FIG. 1B).

On a peripheral portion (a lower stage of the step) of the top portion of the mesa structure MS, an anode electrode 109 having a circling shape (for example, a polygonal frame shape (more specifically, a regular hexagonal frame shape), see FIG. 1B) is provided so as to be in contact with the second multilayer film reflector 107.

As an example, the mesa structure MS is covered with an insulating film 108 constituted by a dielectric except for a portion where the anode electrode 109 is provided and a portion to be an emission port 108a. The emission port 108a is opened in a portion covering the central portion (upper stage of the step) of the top portion of the mesa structure MS of the insulating film 108.

A wiring layer 110 provided along the corner portion, the side surface, and the peripheral portion of the mesa structure MS of the insulating film 108 is connected to the anode electrode 109.

### (Substrate)

The substrate 100 is, for example, a GaAs substrate of a first conductivity type (for example, n-type).

### (Cathode Electrode)

As an example, the cathode electrode 111 (n-side electrode) is solidly provided over substantially the entire region of the back surface of the substrate 100.

The cathode electrode 111 may have a single-layer structure or a laminated structure. The cathode electrode 111 is constituted by, for example, at least one metal (including an alloy) selected from the group including Au, AuGe, Ag, Pd, Pt, Ni, Ti, V, W, Cr, Al, Cu, Zn, Sn, and In. In a case where the cathode electrode 111 has a laminated structure, the cathode electrode 111 is constituted by a material such as Ti/Au, Ti/Al, Ti/Al/Au, Ti/Pt/Au, Ni/Au, AuGe/Ni/Au, Ni/Au/Pt, Ni/Pt, Pd/Pt, or Ag/Pd.

The cathode electrode 111 is electrically connected to the cathode side (negative electrode side) of the laser driver including the driver IC.

### (First Multilayer Film Reflector)

The first multilayer film reflector 101 is, for example, a semiconductor multilayer film reflector. The multilayer film reflector is also referred to as a distributed Bragg reflector. A semiconductor multilayer film reflector which is a type of multilayer film reflector (distributed Bragg reflector) has low light absorption, high reflectance, and conductivity. The first multilayer film reflector 101 is also referred to as a lower DBR.

The first multilayer film reflector 101 is, as an example, a semiconductor multilayer film reflector of the first conductivity type, and has a structure in which a plurality of types (for example, two types) of semiconductor layers (refractive index layers) having different refractive indexes is alternately laminated with an optical thickness of ¼ (λ/4) of an oscillation wavelength λ. Each refractive index layer of the first multilayer film reflector 101 is constituted by an AlGaAs-based compound semiconductor of the first conductivity type (for example, n-type). As an example, the high refractive index layer of the first multilayer film reflector 101 is a GaAs layer, and the low refractive index layer is an AlGaAs layer.

### (Resonator)

The resonator configuration portion R includes first and second cladding layers 102 and 104 in addition to the active layer 103. The first cladding layer 102 can be disposed between the first multilayer film reflector 101 and the active layer 103. The second cladding layer 104 is disposed between the second multilayer film reflector 107 and the active layer 103. The cladding layer is also called a spacer layer.

The first cladding layer 102 is constituted by a first conductivity type (for example, n-type) AlGaAs-based compound semiconductor.

The active layer 103 has a quantum well structure including a barrier layer constituted by, for example, an InGaAs-based compound semiconductor and a quantum well layer. This quantum well structure may be a single quantum well structure (QW structure) or a multiple quantum well structure (MQW structure). The quantum well structure is designed to have an oscillation wavelength of 920 nm to 960 nm, for example.

The second cladding layer 104 is constituted by a second conductivity type (for example, p-type) AlGaAs-based compound semiconductor.

### (Second Multilayer Film Reflector)

The second multilayer film reflector 107 is, as an example, a semiconductor multilayer film reflector of the second conductivity type, and has a structure in which a plurality of types (for example, two types) of semiconductor layers (refractive index layers) having different refractive indexes is alternately laminated with an optical thickness of ¼ wavelength of the oscillation wavelength. Each refractive index layer of the second multilayer film reflector 107 is constituted by a second conductivity type (for example, p-type) AlGaAs-based compound semiconductor. As an example, the high refractive index layer of the second multilayer film reflector 107 is a GaAs layer, and the low refractive index layer is an AlGaAs layer.

### (Insulating Film)

The insulating film 108 is constituted by a dielectric such as SiO₂, SiN, or SiON.

### (Anode Electrode)

The anode electrode 109 (p-side electrode) may have a single-layer structure or a laminated structure. The anode electrode 109 is constituted by, for example, at least one metal (including an alloy) selected from the group including Au, AuGe, Ag, Pd, Pt, Ni, Ti, V, W, Cr,

Al, Cu, Zn, Sn, and In. In a case where the anode electrode 109 has a laminated structure, the anode electrode 109 is constituted by a material such as Ti/Au, Ti/Al, Ti/Al/Au, Ti/Pt/Au, AuGe/Ni/Au, Ni/Au, Ni/Au/Pt, Ni/Pt, Pd/Pt, or Ag/Pd.

### (Wiring Layer)

The wiring layer 110 includes a pad wiring 110a whose end portion is in contact with the anode electrode 109 provided on the insulating film 108 covering the corner portion, the side surface, and the peripheral portion of the mesa structure MS, and a plated wiring 110b provided on the pad wiring 110a. The pad wiring 110a may have a single-layer structure or a laminated structure. The pad wiring 110a is constituted by, for example, at least one metal (including an alloy) selected from the group including Ti/Pt/Ni/Au. In a case where the pad wiring 110a has a laminated structure, the pad wiring 110a is constituted by, for example, a material such as Ti/Pt/Au or Ti/Ni/Au. The plated wiring 110b is constituted by at least one metal (including an alloy) selected from the group including Au, Cu, and Ni, for example.

As an example, the wiring layer 110 is electrically connected to the anode side (positive electrode side) of the laser driver including the driver IC.

### (Semiconductor Layer)

As an example, the longitudinal cross section of the semiconductor layer 105T is not rectangular. Specifically, the semiconductor layer 105T has a tapered shape in which a longitudinal cross section (cross section parallel to the emission direction) protrudes from the active layer 103 side toward the second multilayer film reflector 107 side. More specifically, as an example, the longitudinal cross section of the semiconductor layer 105T has a forward tapered shape (a shape in which the width becomes narrower as the distance from the resonator configuration portion R increases). More specifically, the semiconductor layer 105T has a substantially isosceles trapezoid in which the upper base is smaller than the lower base in the shape of the longitudinal cross section. The semiconductor layer 105T is located at a position corresponding to the emission port 108a. The semiconductor layer 105T may be referred to as a “step pattern”.

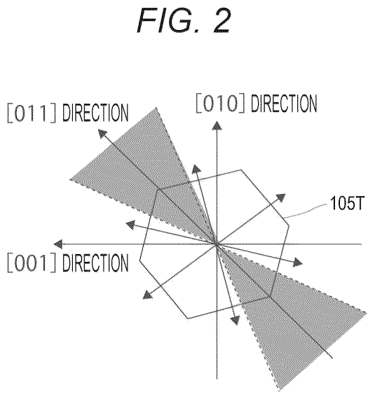

FIG. 2 is a diagram illustrating the relationship between the plan view shape and the crystal orientation of the semiconductor layer 105T. As illustrated in FIG. 2 as an example, the semiconductor layer 105T does not have a {111} A plane on the surface. As an example, the semiconductor layer 105T has a polygonal horizontal cross section (for example, an n-polygon with n≥3).

As an example, the semiconductor layer 105T preferably does not have a plane perpendicular to any crystal orientation within an angle range of ±22.5° from the direction (gray portion in FIG. 2) in a plane including the direction and the direction. This is because, in general, the oxidation confinement layer is likely to be thickened on the {111} A plane, but the {111} A plane partially exists on the slope of the step pattern having a plane perpendicular to any crystal orientation within the angle range. When the slope portion is viewed from a micro viewpoint, the slope is formed such that the {111} A plane alone or the {111} A plane and other surfaces alternately appear regardless of the degree of inclination of the slope.

The semiconductor layer 105T is constituted by, for example, an AlGaAs-based compound semiconductor. More specifically, the semiconductor layer 105T has a graded layer configured such that the Al composition gradually increases from the top surface to the bottom surface between 0% and 35%, and an etching stop layer (about 30 nm to 200 nm) having an Al composition of 40% to 70% and located below the graded layer. The thickness of the graded layer is, for example, about 30 nm to 100 nm.

### (Oxidation Confinement Layer)

As an example, the oxidation confinement layer 106 has a non-oxidized region 106a constituted by AlAs and an oxidized region 106b (black coated portion in FIG. 1A) constituted by an oxide of AlAs (for example, Al₂O₃). The non-oxidized region 106a functions as a current/light passing region. The oxidized region 106b functions as a current/light confinement region. The non-oxidized region 106a is provided at a position corresponding to the emission port 108a.

As an example, the oxidation confinement layer 106 includes an oxidation adjustment structure having an oxidation progress suppressing portion.

The “oxidation adjustment structure” is a structure that controls the boundary position between the non-oxidized region 106a and the oxidized region 106b in the oxidation confinement layer 106 by adjusting parameters related to oxidation such as an oxidation rate, an oxidation distance, and an oxidation time.

The “oxidation progression suppressing portion” has a function of slowing down the oxidation rate or stopping oxidation, for example.

More specifically, the oxidation confinement layer 106 includes a thin film portion 161 as an example of an oxidation progression suppressing portion. The thin film portion 161 preferably exists corresponding to the entire circumference of the non-oxidized region 106a. Note that the oxidation progression suppressing portion may have a cutoff portion in addition to or instead of the thin film portion. The cutoff portion is likely to occur at a position corresponding to a corner portion of the semiconductor layer 105T in the oxidation confinement layer 106.

The thin film portion 161 preferably covers at least a part (for example, all) of the side surface of the semiconductor layer 105T. Here, as an example, the entire thin film portion 161 covers the side surface of the semiconductor layer 105T.

As an example, the non-oxidized region 106a includes a specified film thickness portion 106a1 located between the top surface (upper surface) of the semiconductor layer 105T and the second multilayer film reflector 107, and a thin film portion 106a2 located between the upper portion of the side surface of the semiconductor layer 105T and the second multilayer film reflector 107 and thinner than the specified film thickness portion 106a1. As an example, the oxidized region 106b includes a specified film thickness portion 106b1 located between the peripheral portion of the semiconductor layer 105T of the resonator configuration portion R and the second multilayer film reflector 107, and a thin film portion 106b2 located between the lower portion of the side surface of the semiconductor layer 105T and the second multilayer film reflector 107 and thinner than the specified film thickness portion 106b1.

That is, the thin film portion 161 includes the thin film portion 106a2 of the non-oxidized region 106a and the thin film portion 106b2 of the oxidized region 106b. Furthermore, a boundary between the non-oxidized region 106a and the oxidized region 106b exists in the thin film portion 161.

The oxidation confinement layer 106 preferably does not have a thick film portion. This is because, for example, when the oxidation confinement layer 106 has a thick film portion in addition to the thin film portion, the variation in the oxidation length increases, and the plan view shapes of the non-oxidized region 106a and the oxidized region 106b become more anisotropic.

### <<Operation of Surface Emitting Laser>>

Hereinafter, the operation of the surface emitting laser 10-1 according to Example 1 of the first embodiment of the present technology will be described.

In the surface emitting laser 10-1, the current flowing into the anode electrode 109 from the anode side of the laser driver is narrowed by the oxidation confinement layer 106 via the second multilayer film reflector 107, and injected into the active layer 103 via the semiconductor layer 105T and the second cladding layer 104. At this time, the active layer 103 emits light, and the light is amplified between the first and second multilayer film reflectors 101 and 107 by the active layer 103, reciprocates while being narrowed by the oxidized region 106b of the oxidation confinement layer 106, and is emitted as laser light from the emission port 108a when the oscillation condition is satisfied. The current injected into the active layer 103 flows out to the cathode side of the laser driver via the first cladding layer 102, the first multilayer film reflector 101, and the cathode electrode 111.

### <<Method for Manufacturing Surface Emitting Laser>>

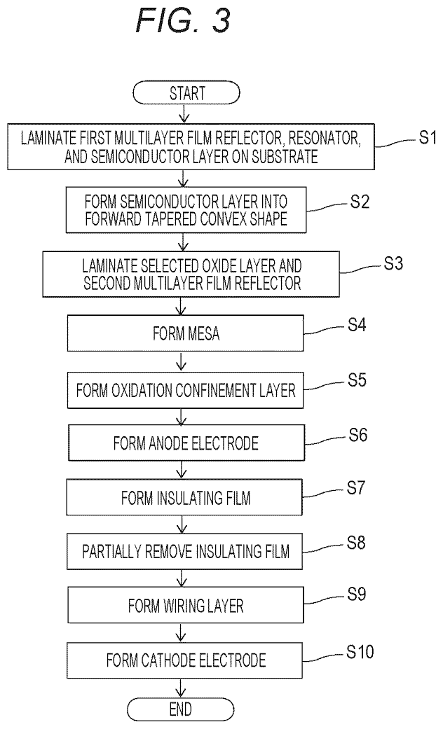

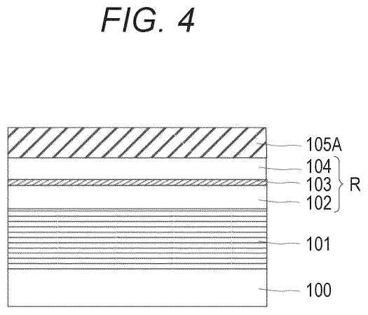

Hereinafter, a method for manufacturing the surface emitting laser 10-1 according to Example 1 of the first embodiment of the present technology will be described with reference to the flowchart of FIG. 3 and the cross-sectional views of FIGS. 4 to 11B.

Here, as an example, a plurality of surface emitting lasers 10-1 is simultaneously generated on one wafer which is a base material of the substrate 100 by a semiconductor manufacturing method using a semiconductor manufacturing apparatus. Next, the plurality of continuous surface emitting lasers 10-1 is separated from each other by dicing to obtain a plurality of chip-shaped surface emitting lasers 10-1.

In the first step S1, the first multilayer film reflector 101, the resonator configuration portion R, and the semiconductor layer 105A are laminated on the substrate 100. Specifically, as illustrated in FIG. 4, the first multilayer film reflector 101, the first cladding layer 102, the active layer 103, the second cladding layer 104, and the semiconductor layer 105A to be the semiconductor layer 105T are laminated in this order on the substrate 100 by using a chemical vapor deposition (CVD) method, for example, a metal organic chemical vapor deposition (MOCVD) method.

The semiconductor layer 105A includes a graded layer (upper layer) and an etching stop layer (lower layer) similar to the semiconductor layer 105T.

In the next step S2, the semiconductor layer 105A is formed into a forward tapered convex shape.

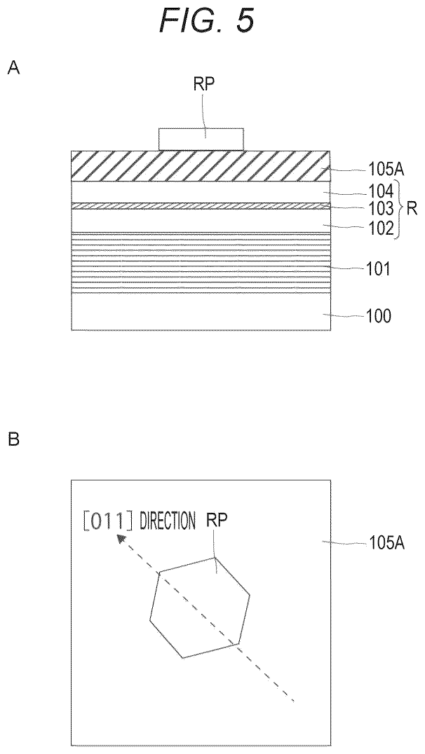

Specifically, first, a resist pattern RP is formed on a position of the semiconductor layer 105A where the semiconductor layer 105T is to be formed (see FIG. 5A). At this time, the resist pattern RP is formed such that the plan view shape is a polygon (for example, a regular hexagon) having no plane perpendicular to the direction (see FIG. 5B).

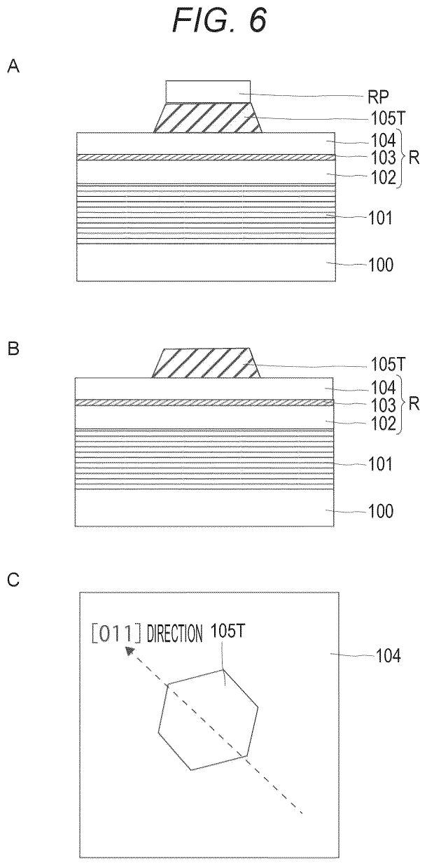

Next, using the resist pattern RP as a mask, the semiconductor layer 105A is etched (wet etching) by, for example, citric acid hydrogen peroxide or the like (see FIG. 6A). At this time, the etching rate of the semiconductor layer 105A changes according to the Al composition of AlGaAs. More specifically, in the semiconductor layer 105A, as the etching of the graded layer progresses, the Al composition becomes higher, the etching becomes slower, and the etching stops in the etching stop layer. As a result, the semiconductor layer 105A is more greatly affected by the side etching in a region having a lower Al composition and is formed into a forward tapered convex shape, and the semiconductor layer 105T is generated.

Finally, the resist pattern RP is removed by acetone treatment or the like (see FIG. 6B). As a result, the semiconductor layer 105T is exposed. The exposed semiconductor layer 105T has a polygonal shape (for example, a regular hexagon) having no plane perpendicular to the direction as the plan view shape (see FIG. 6C).

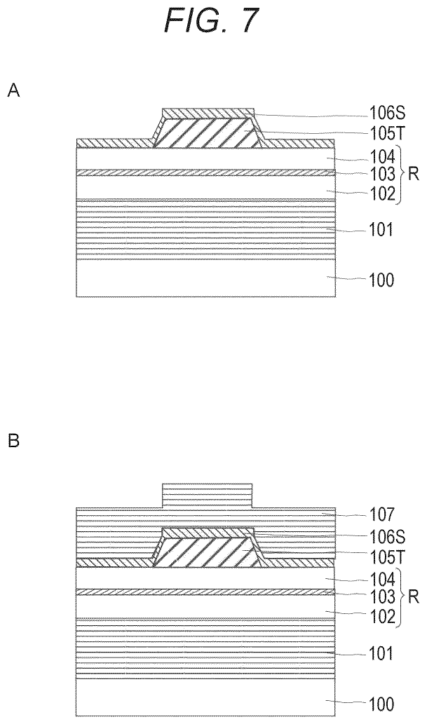

In the next step S3, the selected oxide layer 106S and the second multilayer film reflector 107 are laminated. Specifically, the selected oxide layer 106S and the second multilayer film reflector 107 are grown in this order on the resonator configuration portion R and the semiconductor layer 105T by epitaxial regrowth to generate a laminate (see FIGS. 7A and 7B). At this time, the selected oxide layer 106S and the second multilayer film reflector 107 are formed in a shape following the shape of the semiconductor layer 105T. In particular, the portion of the selected oxide layer 106S covering the side surface of the semiconductor layer 105T is thinned or cut off over the entire circumference of the semiconductor layer 105T.

In the next step S4, a mesa is formed.

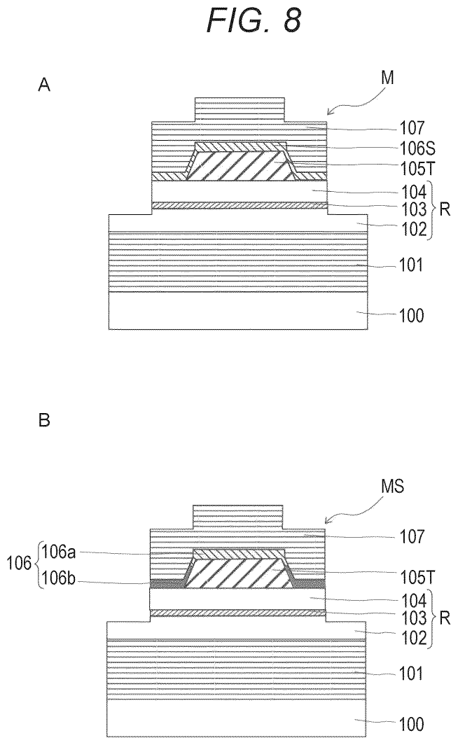

Specifically, first, a resist pattern for forming the mesa M having the mesa structure MS is generated on the second multilayer film reflector 107, and the laminate is etched by, for example, the RIE method using the resist pattern as a mask to form the mesa M (see FIG. 8A). Here, etching is performed until at least the side surface of the active layer 103 is exposed (for example, until the etching bottom surface is located in the first cladding layer 102). Here, the mesa M is formed in a shape (for example, a regular hexagon) corresponding to the shape of the semiconductor layer 105T, for example.

Finally, the resist pattern is removed by acetone treatment or the like.

In the next step S5, the oxidation confinement layer 106 is formed. Specifically, the selected oxide layer 106S of the mesa M (see FIG. 8A) is selectively oxidized to generate the oxidation confinement layer 106 (see FIG. 8B). More specifically, the mesa M is exposed to a water vapor atmosphere, and the selected oxide layer 106S is oxidized from the side surface (Al in AlAs is selectively oxidized). At this time, the oxidation is stopped or the oxidation rate is delayed at the thin film portion or the cutoff portion of the selected oxide layer 106S, and the oxidation is easily stopped. As a result, the oxidation confinement layer 106 including the non-oxidized region 106a and the oxidized region 106b is formed. As a result, the mesa M becomes the mesa structure MS.

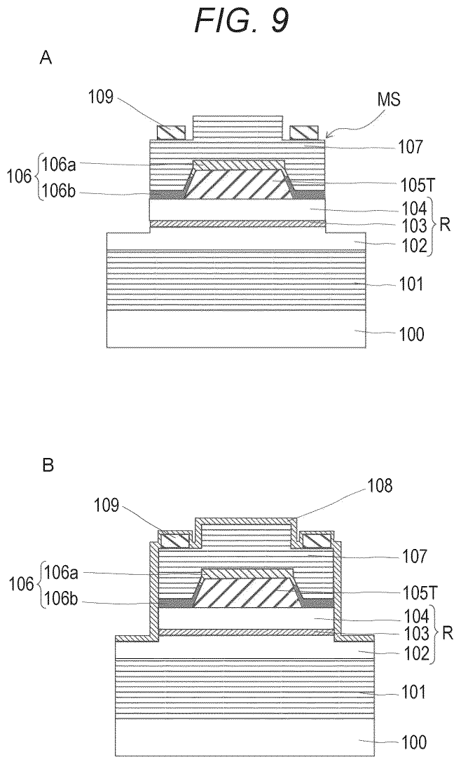

In the next step S6, the anode electrode 109 is formed (see FIG. 9A). Specifically, a film of the electrode material of the anode electrode 109 is formed on the peripheral portion of the top portion of the mesa structure MS (on the second multilayer film reflector 107) by a vapor deposition method, a sputtering method, or the like, and patterning is performed by a lift-off method, for example. At this time, the anode electrode 109 is formed in a shape (for example, a regular hexagonal frame shape) corresponding to the shape of the semiconductor layer 105T as an example.

In the next step S7, the insulating film 108 is formed (see FIG. 9B). Specifically, the insulating film 108 is formed on the laminate on which the anode electrode 109 is formed by, for example, a vapor deposition method, a sputtering method, or the like.

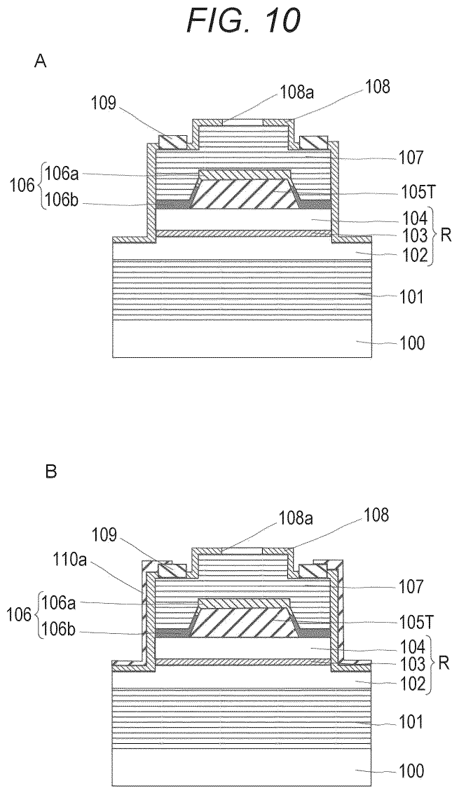

In the next step S8, the insulating film 108 is partially removed (see FIG. 10A). Specifically, the insulating film 108 covering the central portion of the top portion of the mesa structure MS and the insulating film 108 covering the anode electrode 109 are etched and removed. As a result, the emission port 108a is opened and the anode electrode 109 is exposed.

In the next step S9, the wiring layer 110 is formed.

Specifically, first, a wiring material of the pad wiring 110a is formed by, for example, a vapor deposition method, a sputtering method, or the like, and patterning is performed by, for example, a lift-off method (see FIG. 10B). At this time, the pad wiring 110a is patterned so that a part thereof is in contact with the anode electrode 109 and does not enter the inside of the anode electrode 109.

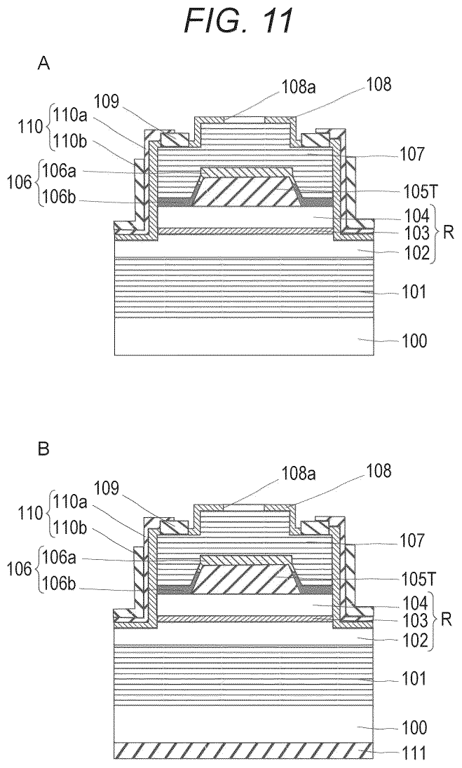

Next, a film of a wiring material of the plated wiring 110b is formed by, for example, a vapor deposition method, a sputtering method, or the like, and patterning is performed by, for example, a lift-off method (see FIG. 11A). At this time, the plated wiring 110b is patterned so as to be in contact with at least the pad wiring 110a.

In the final step S10, the cathode electrode 111 is formed (see FIG. 11B). Specifically, after the back surface of the substrate 100 is ground to be thinned, the electrode material of the cathode electrode 111 is solidly formed over substantially the entire region of the back surface of the substrate 100 by, for example, a vapor deposition method, a sputtering method, or the like.

Thereafter, processing such as annealing is performed to form a plurality of surface emitting lasers 10-1 on one wafer. Thereafter, the plurality of surface emitting lasers 10-1 is separated for each element by dicing to obtain a plurality of chip-shaped surface emitting lasers 10-1.

### <<Effects of Surface Emitting Laser>>

Hereinafter, effects of the surface emitting laser 10-1 according to Example 1 of the first embodiment of the present technology will be described.

The surface emitting laser 10-1 according to Example 1 of the first embodiment of the present technology includes: the first multilayer film reflector 101; the second multilayer film reflector 107; the resonator configuration portion R arranged between the first and second multilayer film reflectors 101 and 107 and including the active layer 103; and the oxidation confinement layer 106 arranged between the second multilayer film reflector 107 and the active layer 103 and including the non-oxidized region 106a and the oxidized region 106b, and the oxidation confinement layer 106 includes the oxidation adjustment structure.

In this case, in the oxidation confinement layer 106, the oxidized region 106b can be isotropically oxidized by the oxidation adjustment structure.

As a result, according to the surface emitting laser 10-1 according to Example 1 of the first embodiment of the present technology, it is possible to provide a surface emitting laser having an isotropically selectively oxidized oxidation confinement layer.

Furthermore, according to the surface emitting laser 10-1, since it is possible to suppress thickening of the oxidation confinement layer 106, it is possible to suppress the occurrence of cracks due to volume fluctuation during selective oxidation, and eventually, it is possible to improve the reliability of the device.

On the other hand, in the conventional surface emitting laser, the oxidation confinement layer is regrown on the step pattern (since the plan view shape is circular, a surface perpendicular to the reverse mesa direction or the forward mesa direction is partially provided, so that the {111} A plane is provided on the slope portion of the step boundary, and the cross section has a forward tapered shape or a reverse tapered shape), but in this case, the oxidation confinement layer is thickened on the {111} A plane as described above, and the oxidation cannot be stopped at a desired position. As a result, it is difficult to form the oxidation confinement layer by isotropic selective oxidation.

The oxidized region 106b is preferably isotropically oxidized.

The surface emitting laser 10-1 further includes the semiconductor layer 105T protruding from the active layer 103 side to the second multilayer film reflector 107 side, the oxidation confinement layer 106 covers the semiconductor layer 105T from the second multilayer film reflector 107 side, and the oxidation adjustment structure has an oxidation progress suppressing portion. In this case, the oxidation confinement layer 106 can control the boundary position between the non-oxidized region 106a and the oxidized region 106b by suppressing the progress of oxidation by the oxidation progress suppressing portion.

The oxidation progression suppressing portion preferably has the thin film portion 161 and/or the cutoff portion. In this case, since the thin film portion 161 and/or the cutoff portion is generated only by covering the semiconductor layer 105T with the oxidation confinement layer 106, the oxidation progress suppressing portion can be easily realized.

The oxidation confinement layer 106 preferably does not have a thick film portion.

The oxidation progression suppressing portion (for example, the thin film portion 161) preferably exists corresponding to the entire circumference of the non-oxidized region 106a. As a result, the shapes of the non-oxidized region 106a and the oxidized region 106b can be made reliably isotropic.

The oxidation progression suppressing portion (for example, the thin film portion 161) is preferably provided on at least a part of the side surface of the semiconductor layer 105T. As a result, the boundary between the non-oxidized region 106a and the oxidized region 106b can be located on the side surface of the semiconductor layer 105T.

The boundary between the non-oxidized region 106a and the oxidized region 106b preferably exists in the thin film portion 161. As a result, it is possible to suppress the oxidized region 106b from extending to a region (for example, a current/light passing region) other than the thin film portion 161 of the oxidation confinement layer 106.

The semiconductor layer 105T preferably has a longitudinal cross section that is not rectangular.

The semiconductor layer 105T preferably has a polygonal horizontal cross section. As a result, at least the {111} A plane can be prevented from appearing in the semiconductor layer 105T.

The semiconductor layer 105T preferably has a forward tapered longitudinal cross section and does not have a plane perpendicular to any crystal orientation within an angle range of ±22.5° from the direction in a plane including the direction and the direction. As a result, it is possible to suppress not only relatively large thickening of the oxidation confinement layer 106 but also relatively small thickening.

### <3. Surface Emitting Laser According to Example 2 of First Embodiment of Present Technology>

### <<Configuration of Surface Emitting Laser>>

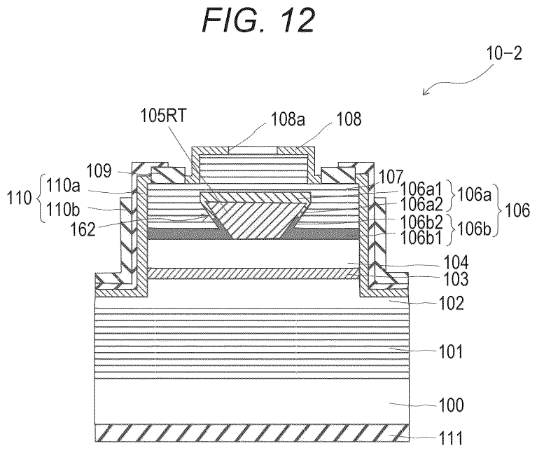

Hereinafter, a configuration of a surface emitting laser according to Example 2 of the first embodiment of the present technology will be described. FIG. 12 is a cross-sectional view of a surface emitting laser 10-2 according to Example 1 of the first embodiment of the present technology.

As illustrated in FIG. 12, the surface emitting laser 10-2 according to Example 2 of the first embodiment has a configuration similar to that of the surface emitting laser 10-1 according to Example 1 except that the longitudinal cross section of the semiconductor layer 105RT has a reverse tapered shape and a part of the oxidation confinement layer 106 is disposed along the semiconductor layer 105RT.

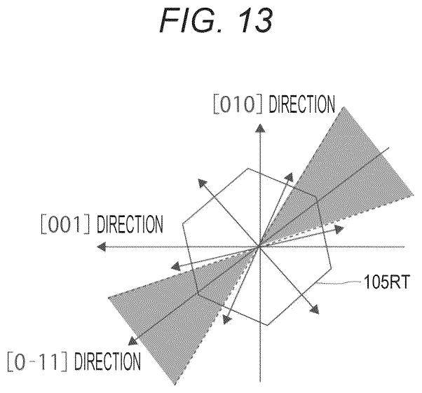

FIG. 13 is a diagram illustrating the relationship between the plan view shape and the crystal orientation of the semiconductor layer 105RT.

As illustrated in FIG. 13, the semiconductor layer 105RT does not have a surface orthogonal to the [0-11] direction (forward mesa direction). As a result, the slope portion of the step boundary does not have the {111} A plane.

Further, the semiconductor layer 105RT preferably does not have a plane perpendicular to any crystal orientation within an angle range of ±22.5° from the [0-11] direction (gray region in FIG. 13) in a plane including the direction and the direction.

The semiconductor 105RT is constituted by, for example, an AlGaAs-based compound semiconductor. More specifically, the semiconductor layer 105RT has a graded layer configured such that the Al composition gradually decreases from the top surface to the bottom surface between 0% and 35%, and an etching stop layer having an Al composition of 40% to 70% and located below the graded layer.

The thickness of the graded layer is, for example, about 30 nm to 100 nm.

The surface emitting laser 10-2 operates similarly to the surface emitting laser 10-1 according to Example 1.

### <<Method for Manufacturing Surface Emitting Laser>>

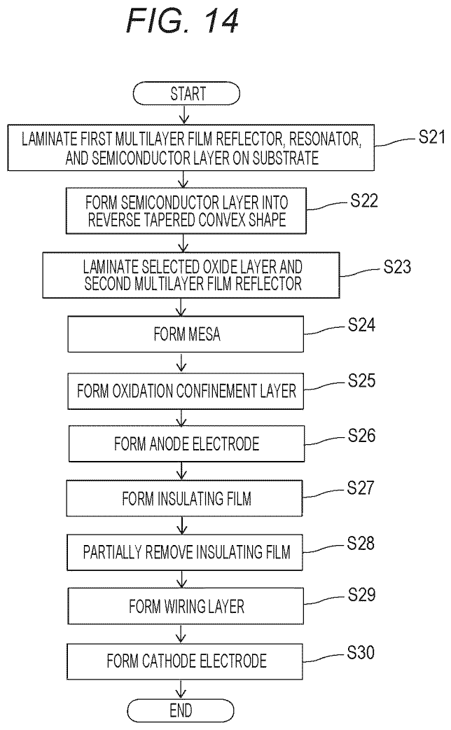

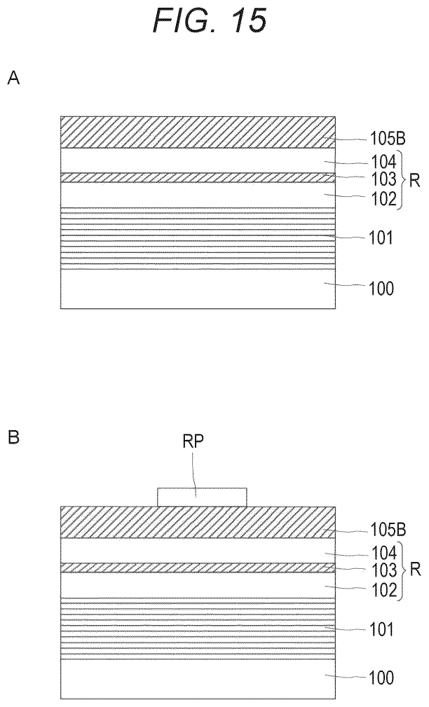

Hereinafter, a method for manufacturing the surface emitting laser 10-2 according to Example 2 of the first embodiment of the present technology will be described with reference to the flowchart of FIG. 14 and the cross-sectional views of FIGS. 15A to 21B.

Here, as an example, a plurality of surface emitting lasers 10-2 is simultaneously generated on one wafer which is a base material of the substrate 100 by a semiconductor manufacturing method using a semiconductor manufacturing apparatus. Next, the plurality of continuous surface emitting lasers 10-2 is separated from each other by dicing to obtain a plurality of chip-shaped surface emitting lasers 10-2.

In the first step S21, the first multilayer film reflector 101, the resonator configuration portion R, and the semiconductor layer 105B are laminated on the substrate 100. Specifically, as illustrated in FIG. 15A, a first multilayer film reflector 101, a first cladding layer 102, an active layer 103, a second cladding layer 104, and a semiconductor layer 105B to be a semiconductor layer 105RT are laminated in this order on a substrate 100 by using a chemical vapor deposition (CVD) method, for example, a metal organic chemical vapor deposition (MOCVD) method.

The semiconductor layer 105B includes a graded layer (upper layer) and an etching stop layer (lower layer) similar to the semiconductor layer 105RT.

In the next step S22, the semiconductor layer 105B is formed into a reverse tapered convex shape.

Specifically, first, a resist pattern RP is formed on a position where the semiconductor layer 105RT of the semiconductor layer 105B is to be formed (see FIG. 15B). At this time, the resist pattern RP is formed such that the plan view shape is a polygon (for example, a regular hexagon) having no plane perpendicular to the [0-11] direction.

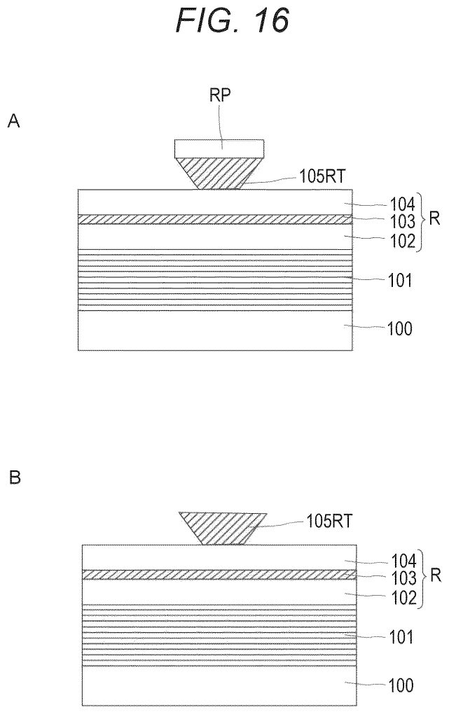

Next, using the resist pattern RP as a mask, the semiconductor layer 105B is etched (wet etching) by, for example, citric acid hydrogen peroxide or the like (see FIG. 16A). At this time, the etching rate of the semiconductor layer 105B changes according to the Al composition of AlGaAs. More specifically, in the semiconductor layer 105B, as the etching of the graded layer progresses, the Al composition decreases, the etching becomes faster, and the etching stops in the etching stop layer. As a result, the semiconductor layer 105B is more greatly affected by the side etching in a region having a lower Al composition and is formed into a reverse tapered convex shape, and the semiconductor layer 105RT is generated.

Finally, the resist pattern RP is removed by acetone treatment or the like (see FIG. 16B). As a result, the semiconductor layer 105RT is exposed. The exposed semiconductor layer 105RT has a polygonal shape (for example, a regular hexagon) in which the plan view shape has no plane perpendicular to the [0-11] direction, and as a result, the slope of the step pattern does not partially include the {111} A plane.

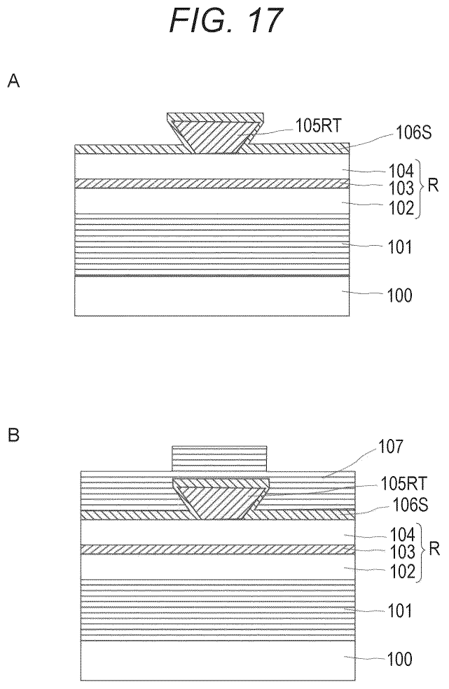

In the next step S23, the selected oxide layer 106S and the second multilayer film reflector 107 are laminated. Specifically, the selected oxide layer 106S and the second multilayer film reflector 107 are grown in this order on the resonator configuration portion R and the semiconductor layer 105RT by epitaxial regrowth to generate a laminate (see FIGS. 17A and 17B). At this time, the selected oxide layer 106S and the second multilayer film reflector 107 are formed in a shape following the shape of the semiconductor layer 105RT. In particular, the portion of the selected oxide layer 106S covering the side surface of the semiconductor layer 105RT is thinned or cut off over the entire circumference of the semiconductor layer 105RT.

In the next step S24, a mesa is formed.

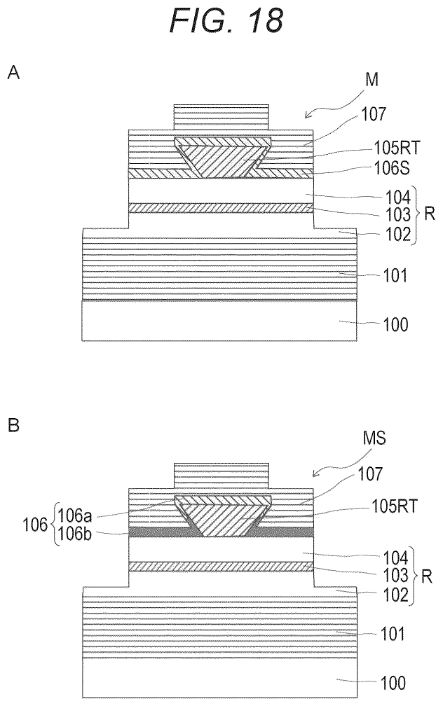

Specifically, first, a resist pattern for forming the mesa M having the mesa structure MS is generated on the second multilayer film reflector 107, and the laminate is etched by, for example, the RIE method using the resist pattern as a mask to form the mesa M (see FIG. 18A). Here, etching is performed until at least the side surface of the active layer 103 is exposed (for example, until the etching bottom surface is located in the first cladding layer 102). The mesa M is formed in a shape (for example, a regular hexagon) corresponding to the shape of the semiconductor layer 105RT, for example.

Finally, the resist pattern is removed by acetone treatment or the like.

In the next step S25, the oxidation confinement layer 106 is formed. Specifically, the selected oxide layer 106S of the mesa M (see FIG. 18A) is selectively oxidized to generate the oxidation confinement layer 106 (see FIG. 18B). More specifically, the mesa M is exposed to a water vapor atmosphere, and the selected oxide layer 106S is oxidized from the side surface (Al in AlAs is selectively oxidized). At this time, oxidation stops in the thin film portion of the selected oxide layer 106S. As a result, the oxidation confinement layer 106 including the non-oxidized region 106a and the oxidized region 106b is formed. As a result, the mesa M becomes the mesa structure MS.

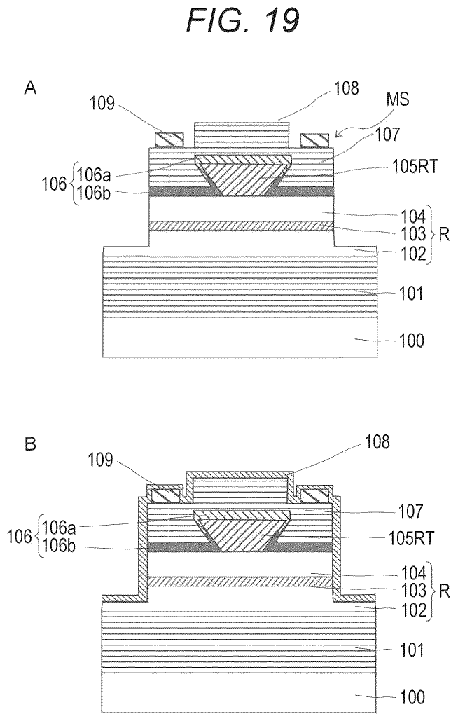

In the next step S26, the anode electrode 109 is formed (see FIG. 19A). Specifically, a film of the electrode material of the anode electrode 109 is formed on the peripheral portion of the top portion of the mesa structure MS (on the second multilayer film reflector 107) by a vapor deposition method, a sputtering method, or the like, and patterning is performed by a lift-off method, for example. At this time, the anode electrode 109 is formed in a shape (for example, a regular hexagonal frame shape) corresponding to the shape of the semiconductor layer 105RT.

In the next step S27, the insulating film 108 is formed (see FIG. 19B). Specifically, the insulating film 108 is formed on the laminate on which the anode electrode 109 is formed by, for example, a vapor deposition method, a sputtering method, or the like.

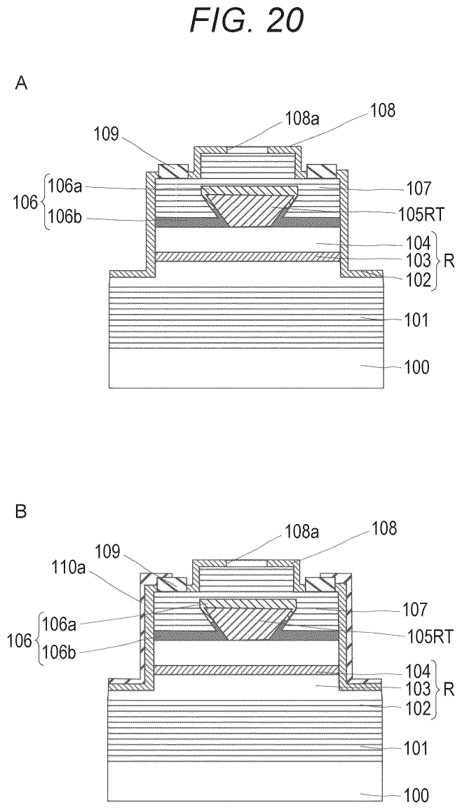

In the next step S28, the insulating film 108 is partially removed (see FIG. 20A). Specifically, the insulating film 108 covering the central portion of the top portion of the mesa structure MS and the insulating film 108 covering the anode electrode 109 are etched and removed. As a result, the emission port 108a is opened and the anode electrode 109 is exposed.

In the next step S29, the wiring layer 110 is formed.

Specifically, first, a wiring material of the pad wiring 110a is formed by, for example, a vapor deposition method, a sputtering method, or the like, and patterning is performed by, for example, a lift-off method (see FIG. 20B). At this time, the pad wiring 110a is patterned so that a part thereof is in contact with the anode electrode 109 and does not enter the inside of the anode electrode 109.

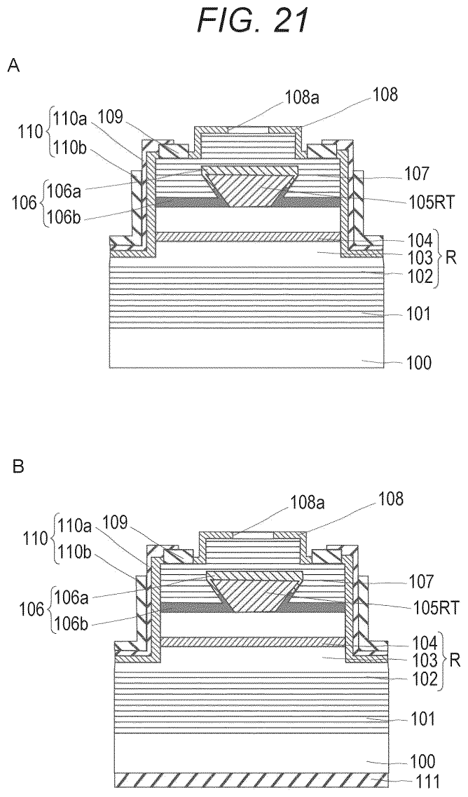

Next, a film of a wiring material of the plated wiring 110b is formed by, for example, a vapor deposition method, a sputtering method, or the like, and patterning is performed by, for example, a lift-off method (see FIG. 21A). At this time, the plated wiring 110b is patterned so as to be in contact with at least the pad wiring 110a.

In the final step S30, the cathode electrode 111 is formed (see FIG. 21B). Specifically, after the back surface of the substrate 100 is ground to be thinned, the electrode material of the cathode electrode 111 is solidly formed over substantially the entire region of the back surface of the substrate 100 by, for example, a vapor deposition method, a sputtering method, or the like.

Thereafter, processing such as annealing is performed to form a plurality of surface emitting lasers 10-2 on one wafer. Thereafter, the plurality of surface emitting lasers 10-2 is separated for each element by dicing to obtain a plurality of chip-shaped surface emitting lasers 10-2.

The surface emitting laser 10-2 according to Example 2 has an effect similar to that of the surface emitting laser 10-1 according to Example 1.

### <4. Surface Emitting Laser According to Second Embodiment of Present Technology>

### <<Configuration of Surface Emitting Laser>>

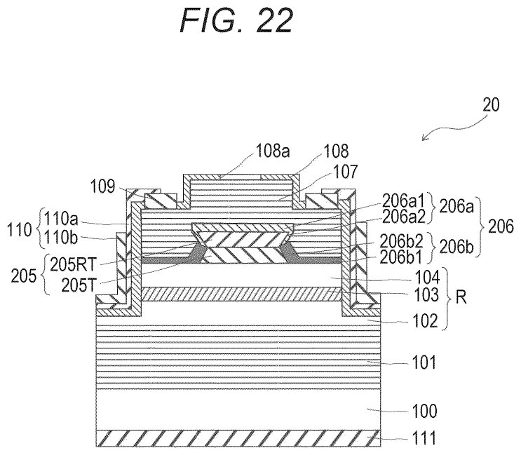

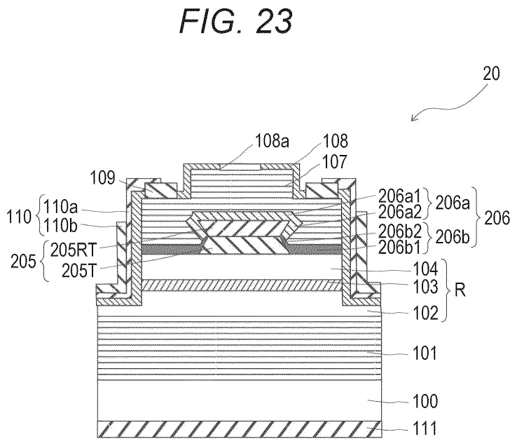

Hereinafter, a configuration of a surface emitting laser according to a second embodiment of the present technology will be described. FIG. 22 is a cross-sectional view illustrating a cross section perpendicular to the direction (reverse mesa direction) of the surface emitting laser 20 according to the second embodiment of the present technology. FIG. 23 is a cross-sectional view illustrating a cross section perpendicular to the [0-11] direction (forward mesa direction) of the surface emitting laser 20 according to the second embodiment of the present technology.

The surface emitting laser 20 according to the second embodiment has a configuration similar to that of the surface emitting laser 10-1 according to Example 1 of the first embodiment except that the oxidation confinement layer 206 has a thin film portion and a thick film portion in a predetermined longitudinal cross section (for example, longitudinal cross sections illustrated in FIGS. 22 and 22).

The semiconductor layer 205 has a {111} A plane on a surface thereof, and a longitudinal cross section thereof has a forward tapered shape and a reverse tapered shape. The horizontal cross section of the semiconductor layer 205 can be, for example, a circle, a polygon, or the like.

As illustrated in FIGS. 22 and 23, the semiconductor layer 205 has a laminated structure in which a reverse tapered semiconductor layer 205RT is an upper layer and a forward tapered semiconductor layer 205T is a lower layer.

The semiconductor layer 205RT is constituted by, for example, an AlGaAs-based compound semiconductor. More specifically, the semiconductor layer 105RT has a first graded layer configured such that the Al composition gradually decreases from the top surface to the bottom surface between 0% and 35%.

The semiconductor layer 205T is constituted by, for example, an AlGaAs-based compound semiconductor. More specifically, the semiconductor layer 205T has a second graded layer configured such that the Al composition gradually increases from the top surface to the bottom surface between 0% and 35%, and an etching stop layer having an Al composition of 40% to 70% and located below the second graded layer.

The total thickness of the first and second graded layers is, for example, about 30 nm to 100 nm.

The semiconductor layer 205 may have both surfaces perpendicular to the direction (reverse mesa direction) and the [0-11] direction (forward mesa direction), or may have only one of the surfaces.

As illustrated in FIG. 22, in the oxidation confinement layer 206, the oxidized region 206b has a specified film thickness portion 206b1 located between the resonator configuration portion R and the second multilayer film reflector 107 and a thick film portion 206b2 provided between the side surface of the semiconductor layer 205T and the second multilayer film reflector 107 and thicker than the specified film thickness portion 206b1 in a cross section perpendicular to the direction (reverse mesa direction).

As illustrated in FIG. 22, in the oxidation confinement layer 206, the non-oxidized region 206a has a specified film thickness portion 206a1 located between the semiconductor layer 205RT and the second multilayer film reflector 107 and a thin film portion 206a2 provided between the side surface of the semiconductor layer 205RT and the second multilayer film reflector 107 and thinner than the specified film thickness portion 206a1 in a cross section perpendicular to the direction (reverse mesa direction). Note that the oxidation confinement layer 206 may have a cutoff portion instead of or in addition to the thin film portion 206a2.

As illustrated in FIG. 23, in the oxidation confinement layer 206, the oxidized region 206b has a specified film thickness portion 206b1 located between the resonator configuration portion R and the second multilayer film reflector 107 and a thin film portion 206b2 provided between the side surface of the semiconductor layer 205T and the second multilayer film reflector 107 and thinner than the specified film thickness portion 206b1 in a cross section perpendicular to the [0-11] direction (forward mesa direction). Note that the oxidation confinement layer 206 may have a cutoff portion instead of or in addition to the thin film portion 206b2.

As illustrated in FIG. 23, in the oxidation confinement layer 206, the non-oxidized region 206a has a specified film thickness portion 206a1 located between the semiconductor layer 205RT and the second multilayer film reflector 107 and a thick film portion 206a2 provided between the side surface of the semiconductor layer 205RT and the second multilayer film reflector 107 and thicker than the specified film thickness portion 206a1 in a cross section perpendicular to the [0-11] direction (forward mesa direction).

The oxidation confinement layer 206 may have a boundary between the non-oxidized region 206a and the oxidized region 206b at a position corresponding to a boundary between the forward tapered shape and the reverse tapered shape of the semiconductor layer 205.

Note that the semiconductor layer 205 and the oxidation confinement layer 206 have intermediate properties (properties having a thick film portion and a thin film portion having different film thickness differences) of the cross sections illustrated in FIGS. 22 and 23 in a longitudinal cross section other than the longitudinal cross sections illustrated in FIGS. 22 and 23.

The surface emitting laser 20 according to the second embodiment performs an operation similar to that of the surface emitting laser 10-1 according to Example 1 of the first embodiment.

### <<Method for Manufacturing Surface Emitting Laser>>

Hereinafter, a method for manufacturing the surface emitting laser 20 according to the second embodiment of the present technology will be described. The method for manufacturing the surface emitting laser 20 is performed in a procedure similar to that of the flowchart of FIG. 3 or 14 except for the second step.

In the second step in the method for manufacturing the surface emitting laser 20, the semiconductor layer 205B to be the semiconductor layer 205RT is formed into a reverse tapered convex shape, and the semiconductor layer 205A to be the semiconductor layer 205T is formed into a forward tapered convex shape.

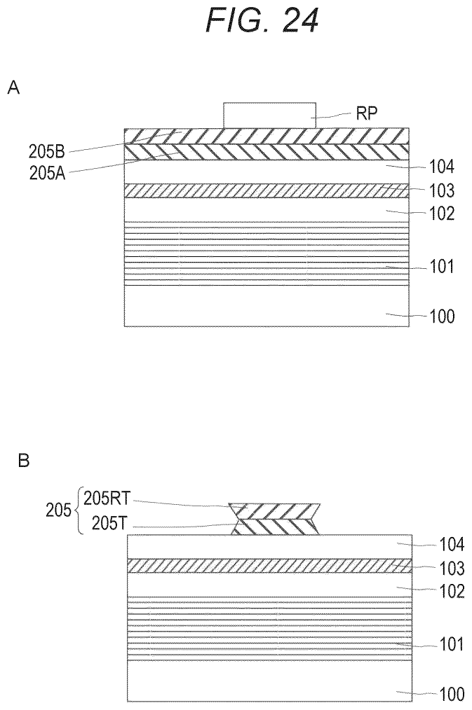

Specifically, first, the first multilayer film reflector 101, the first cladding layer 102, the active layer 103, the second cladding layer 104, the semiconductor layer 205A, and the semiconductor layer 205B are laminated in this order on the substrate 100. Next, a resist pattern RP is formed at a position of the semiconductor layer 205B where the semiconductor layer 205 is to be formed (see FIG. 24A). The plan view shape of the resist pattern is a shape corresponding to the plan view shape of the semiconductor layer 205.

Next, using the resist pattern RP as a mask, the semiconductor layers 205B and 205A are sequentially etched (wet etching) by, for example, citric acid hydrogen peroxide or the like (see FIG. 24B). At this time, the etching rate of the semiconductor layer 205B changes according to the Al composition of AlGaAs. More specifically, in the semiconductor layer 205B, as the etching of the graded layer progresses, the Al composition becomes lower and the etching becomes faster. As a result, the semiconductor layer 205B is more greatly affected by the side etching in a region having a lower Al composition and is formed into a reverse tapered convex shape, and the semiconductor layer 205RT is generated. The etching of the semiconductor layer 205A is started simultaneously with the end of the etching of the semiconductor layer 205B. The etching rate of the semiconductor layer 205A also changes according to the Al composition of AlGaAs. More specifically, in the semiconductor layer 205A, as the etching of the graded layer progresses, the Al composition becomes higher and the etching becomes slower. As a result, the semiconductor layer 205A is more greatly affected by the side etching in a region having a lower Al composition and is formed into a forward tapered convex shape, and the semiconductor layer 205T is generated.

Finally, the resist pattern RP is removed by acetone treatment or the like (see FIG. 24B). As a result, the semiconductor layer 205 is exposed.

### <<Effects of Surface Emitting Laser>>

According to the surface emitting laser 20 according to the second embodiment of the present technology, the longitudinal cross section of the semiconductor layer 205 has both a forward tapered shape and a reverse tapered shape. Since the {111} A plane at least partially appears on a forward tapered slope in a cross section perpendicular to the direction (reverse mesa direction) (former) and on a reverse tapered slope in a cross section perpendicular to the [0-11] direction (forward mesa direction) (latter), the oxidation confinement layer tends to be thickened. On the other hand, since the {111} A plane does not appear on the reverse tapered slope in the former case and the forward tapered slope in the latter case, the oxidation confinement layer tends to be thinned or cut off. As a result, in each longitudinal cross section, since the oxidation confinement layer 206 provided along the semiconductor layer 205 has a thin film portion or a cutoff portion in any case, the oxidized region 206b is isotropically oxidized, and the semiconductor layer 205 is not restricted by the horizontal cross-sectional shape and the crystal orientation, so that the degree of freedom in design is high.

### <5. Surface Emitting Laser According to Example 1 of Third Embodiment of Present Technology>

### <<Configuration of Surface Emitting Laser>>

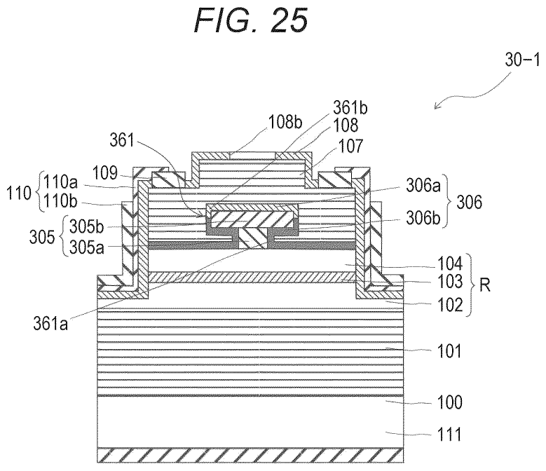

Hereinafter, a configuration of a surface emitting laser according to Example 1 of a third embodiment of the present technology will be described. FIG. 25 is a cross-sectional view of a surface emitting laser 30-1 according to Example 1 of the third embodiment of the present technology.

As illustrated in FIG. 25, the surface emitting laser 30-1 according to the third embodiment has a configuration similar to that of the surface emitting laser 10-1 according to Example 1 of the first embodiment except that the oxidation adjustment structure of the oxidation confinement layer 306 has a route-around portion 361 instead of the oxidation progress suppressing portion.

In the surface emitting laser 30-1, the oxidation confinement layer 306 including the non-oxidized region 306a and the oxidized region 306b covers the semiconductor layer 305 protruding from the active layer 103 side to the second multilayer film reflector 107 side from the second multilayer film reflector 107 side.

The semiconductor layer 305 has, for example, an eaves shape.

As an example, the semiconductor layer 305 has a laminated structure in which a plurality of (for example, two) semiconductor layers (for example, AlGaAs layers) having a semiconductor layer 305a (for example, an AlGaAs layer) having a relatively low Al composition as a lower layer and a semiconductor layer 305b (for example, an AlGaAs layer) having a relatively high Al composition as an upper layer is laminated. Here, the semiconductor layer 305a is, for example, Al_{0.1}GaAs, and the semiconductor layer 305b is, for example, Al_{0.35}GaAs.

As an example, the semiconductor layer 305a functions as an oxidation confinement diameter setting portion that sets the oxidation confinement diameter of the oxidation confinement layer 306.

As an example, the semiconductor layer 305b has an overhang portion overhanging from the semiconductor layer 305a as an oxidation confinement diameter setting portion.

At least a part (for example, all) of the route-around portion 361 extends along the semiconductor layer 305.

The route-around portion 361 includes a first portion 361a extending along the semiconductor layer 305a as an oxidation confinement diameter setting portion, and a second portion 361b continuous with the first portion 361a and extending along the overhang portion of the semiconductor layer 305b.

As an example, in the oxidation confinement layer 306, a boundary between the non-oxidized region 306a and the oxidized region 306b exists in the route-around portion 361. More specifically, as an example, the boundary between the non-oxidized region 306a and the oxidized region 306b exists in the second portion 361b of the route-around portion 361. More specifically, as an example, the boundary between the non-oxidized region 306a and the oxidized region 306b exists in a portion covering the side surface of the overhang portion of the semiconductor layer 305 in the second portion 361b of the route-around portion 361. Note that the boundary between the non-oxidized region 306a and the oxidized region 306b may exist in the first portion 361a of the route-around portion 361.

The surface emitting laser 30-1 according to Example 1 of the third embodiment performs an operation similar to that of the surface emitting laser 10-1 according to Example 1 of the first embodiment.

### <<Method for Manufacturing Surface Emitting Laser>>

Hereinafter, a method for manufacturing the surface emitting laser 30-1 according to Example 1 of the third embodiment of the present technology will be described. The method for manufacturing the surface emitting laser 30-1 is performed in a procedure similar to that of the flowchart of FIG. 3 or 14 except for the second step.

In the second step of the method for manufacturing the surface emitting laser 30-1, a laminate including the semiconductor layer 305B to be the semiconductor layer 305b and the semiconductor layer 305A to be the semiconductor layer 305a is formed in an eaves shape.

Specifically, first, the first multilayer film reflector 101, the first cladding layer 102, the active layer 103, the second cladding layer 104, the semiconductor layer 305A, and the semiconductor layer 305B are laminated in this order on the substrate 100.

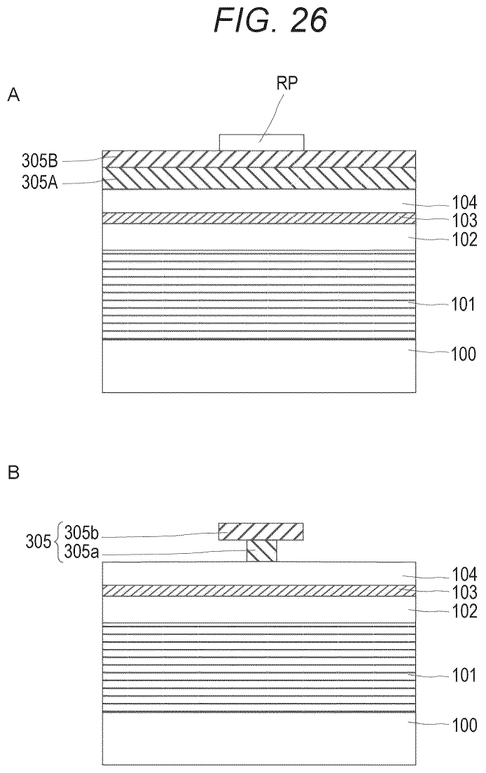

Next, a resist pattern RP is formed at a position of the semiconductor layer 305B where the semiconductor layer 305 is to be formed (see FIG. 26A). The plan view shape of the resist pattern RP is a shape corresponding to the plan view shape of the semiconductor layer 305.

Next, using the resist pattern RP as a mask, the semiconductor layers 305B and 305A are sequentially etched (wet etching) by, for example, citric acid hydrogen peroxide or the like. At this time, the semiconductor layers 305B and 305A are etched at an etching rate corresponding to each Al composition. More specifically, the semiconductor layer 305B having a relatively high Al composition is etched at a relatively slow etching rate (relatively small side etching) to generate the semiconductor layer 305b. The etching of the semiconductor layer 305A is started simultaneously with the end of the etching of the semiconductor layer 305B. The semiconductor layer 305A having a relatively low Al composition is etched at a relatively fast etching rate (relatively large amount of side etching) to generate the semiconductor layer 305a. As a result, the eaves shaped semiconductor layer 305 having the semiconductor layer 305a as a lower layer and the semiconductor layer 305b as an upper layer is generated.

Finally, the resist pattern RP is removed by acetone treatment or the like (see FIG. 26B). As a result, the semiconductor layer 305 is exposed.

### <<Effects of Surface Emitting Laser>>

In the surface emitting laser 30-1, since the oxidation adjustment structure has the route-around portion 361, oxidation can be stopped at a desired position (position where the oxidation confinement diameter can be secured) of the oxidation confinement layer 306 in consideration of the oxidation time. In this case, the oxidation adjustment structure can stop the oxidation at a desired position of the oxidation confinement layer 306 without strictly controlling the oxidation time.

Furthermore, in the surface emitting laser 30-1, the oxidation confinement layer 306 is isotropically oxidized, and the semiconductor layer 305 is not restricted by the horizontal cross-sectional shape and the crystal orientation, so that the degree of freedom in design is high.

In addition, when the lower portion of the upper portion and the lower portion facing each other in the oxidized region 306b is oxidized, stress is applied to the upper portion due to the volume fluctuation of the lower portion, and the oxidation rate of the upper portion is reduced. As a result, selective oxidation is further facilitated.

### <6. Surface Emitting Laser According to Example 2 of Third Embodiment of Present Technology>

### <<Configuration of Surface Emitting Laser>>

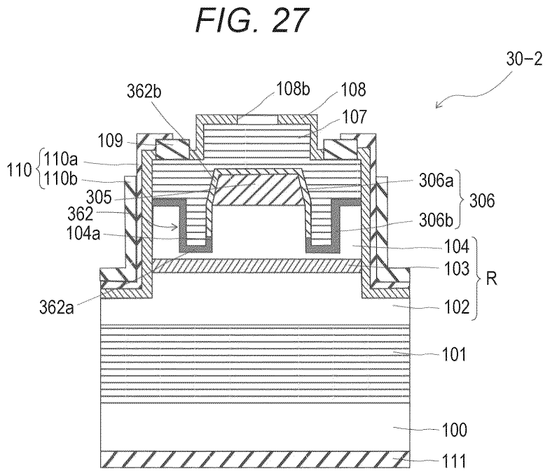

Hereinafter, a configuration of a surface emitting laser according to Example 2 of the third embodiment of the present technology will be described. FIG. 27 is a cross-sectional view of a surface emitting laser 30-2 according to Example 2 of the third embodiment of the present technology.

The surface emitting laser 30-2 according to Example 2 of the third embodiment has substantially a configuration similar to that of the surface emitting laser 30-1 according to Example 1 except that a groove 104a is provided on the surface of the resonator configuration portion R on the second multilayer film reflector 107 side and at least a part of the route-around portion 362 extends along the groove 104a.

The surface emitting laser 30-2 includes a semiconductor layer 305 protruding from the active layer 103 side to the second multilayer film reflector 107 side. The semiconductor layer 305 is provided on the second cladding layer 104. As an example, the semiconductor layer 305 is constituted by an AlGaAs layer having a substantially constant Al composition in the thickness direction.

In the surface emitting laser 30-2, the oxidation confinement layer 306 including the non-oxidized region 306a and the oxidized region 306b covers the semiconductor layer 305 from the second multilayer film reflector 107 side.

As an example, the groove 104a is a circling groove provided in the second cladding layer 104 and circling along the outer periphery of the semiconductor layer 305.

The route-around portion 362 has a first portion 362a extending along the groove 104a and a second portion 362b continuous with the first portion 362a and extending along the semiconductor layer 305.

As an example, the boundary between the non-oxidized region 306a and the oxidized region 306b exists in the route-around portion 362. More specifically, as an example, the boundary between the non-oxidized region 306a and the oxidized region 306b exists in the first portion 362a of the route-around portion 362. More specifically, as an example, the boundary between the non-oxidized region 306a and the oxidized region 306b exists in a portion covering the side surface on the inner side of the groove 104a in the first portion 362a of the route-around portion 362. Note that the boundary between the non-oxidized region 306a and the oxidized region 306b may exist in the second portion 362b of the route-around portion 362.

### <<Method for Manufacturing Surface Emitting Laser>>

Hereinafter, a method for manufacturing the surface emitting laser 30-2 according to Example 2 of the third embodiment of the present technology will be described. The method for manufacturing the surface emitting laser 30-2 is performed in a procedure similar to that of the flowchart of FIG. 3 or 14 except for the second step.

In the second step in the method for manufacturing the surface emitting laser 30-2, the semiconductor layer 305 is protruding, and the groove 104a that goes around the outer periphery of the semiconductor layer 305 is formed.

Specifically, first, a semiconductor base material layer to be the first multilayer film reflector 101, the first cladding layer 102, the active layer 103, the second cladding layer 104, and the semiconductor layer 305 is laminated in this order on the substrate 100.

Next, a resist pattern RP1 is formed at a position where the semiconductor layer 305 of the semiconductor base material layer is to be formed. The plan view shape of the resist pattern RP1 is a shape corresponding to the plan view shape of the semiconductor layer 305.

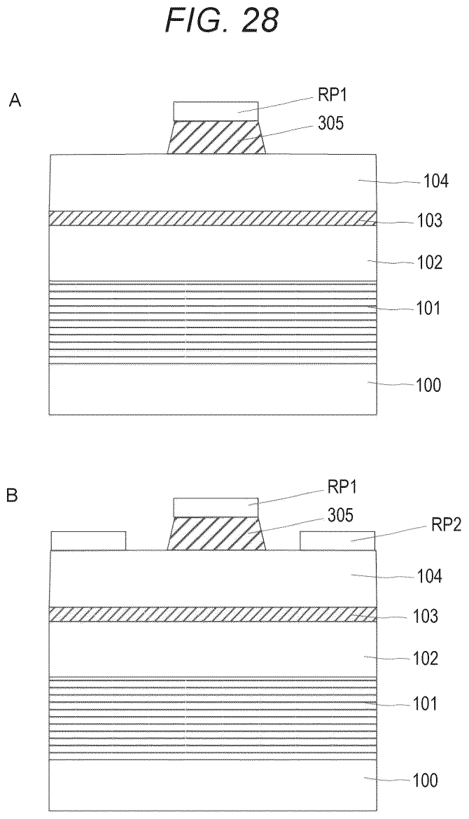

Next, using the resist pattern RP1 as a mask, the semiconductor base material layer is etched (wet etching) by, for example, citric acid hydrogen peroxide or the like (see FIG. 28A). As a result, the semiconductor layer 305 is protruding.

Next, a resist pattern RP2 for forming the groove 104a is formed on the second cladding layer 104 (see FIG. 28B).

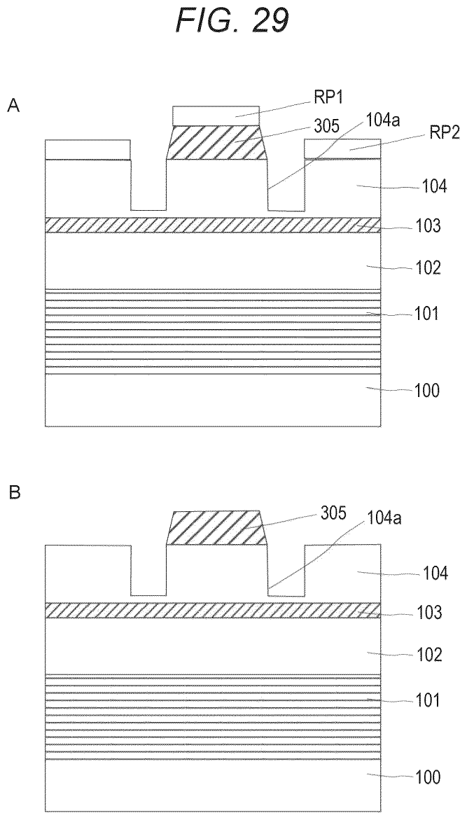

Next, using the resist patterns RP1 and RP2 as masks, the second cladding layer 104 is etched with, for example, phosphoric acid hydrogen peroxide or the like to form the groove 104a (see FIG. 29A).

Finally, the resist patterns RP1 and RP2 are removed by acetone treatment or the like (see FIG. 29B).

### <<Effects of Surface Emitting Laser>>

The surface emitting laser 30-2 has an effect similar to that of the surface emitting laser 30-1 according to Example 1. To supplement, when the outer portion of the outer portion and the inner portion facing each other in the first portion 362a of the route-around portion 362 is oxidized, stress is applied to the inner portion due to the volume fluctuation of the outer portion, and the oxidation rate of the inner portion is reduced. As a result, selective oxidation is further facilitated.

### <7. Surface Emitting Laser According to Modification 1 of First Embodiment of Present Technology>

Hereinafter, a surface emitting laser according to Modification 1 of the first embodiment of the present technology will be described.

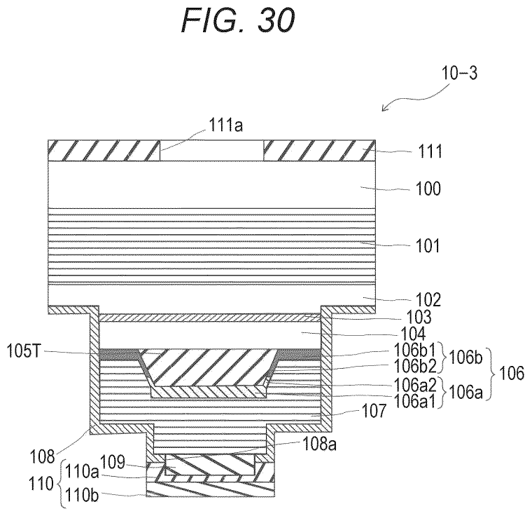

FIG. 30 is a cross-sectional view of a surface emitting laser 10-3 according to Modification 1 of the first embodiment.

The surface emitting laser 10-3 has substantially a configuration similar to that of the surface emitting laser 10-1 according to Example 1 of the first embodiment except that it is a back surface emission type that emits light from the back surface side of the substrate 100.

In the surface emitting laser 10-3, as illustrated in FIG. 30, an emission port 111a is formed in the cathode electrode 111. In the surface emitting laser 10-3, the anode electrode 109 is provided at the central portion of the top portion of the mesa structure, the pad wiring 110a is provided so as to be in contact with the anode electrode 109, and the plated wiring 110b is provided so as to be in contact with the pad wiring 110a.

The surface emitting laser 10-3 performs an operation similar to that of the surface emitting laser 10-1 according to Example 1 of the first embodiment, is manufactured by substantially a similar manufacturing method, and has a similar effect.

### <8. Surface Emitting Laser According to Modification 2 of First Embodiment of Present Technology>

Hereinafter, a surface emitting laser according to Modification 2 of the first embodiment of the present technology will be described.

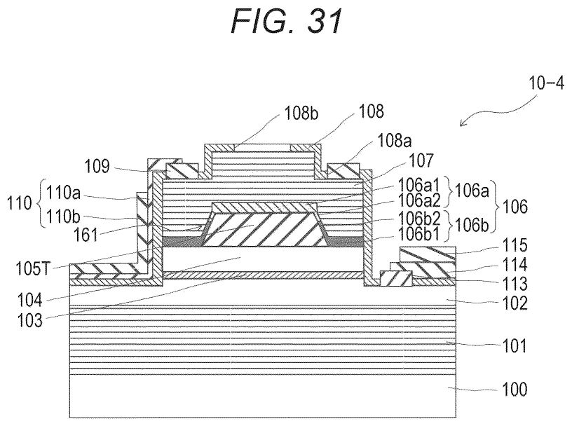

FIG. 31 is a cross-sectional view of a surface emitting laser 10-4 according to Modification 2 of the first embodiment.

The surface emitting laser 10-4 has substantially a configuration similar to that of the surface emitting laser 10-1 according to Example 1 of the first embodiment except that the cathode electrode 113 is provided in contact with the first cladding layer 102 around the mesa structure.

In the surface emitting laser 10-4, the pad wiring 114 is provided on the cathode electrode 113, and the plated wiring 115 is provided on the pad wiring 114.

According to the surface emitting laser 10-4, an operation similar to that of the surface emitting laser 10-1 according to Example 1 of the first embodiment (however, the current path does not pass through the substrate 100) is performed, and has a similar effect.

### <9. Surface Emitting Laser According to Modification 3 of First Embodiment of Present Technology>

Hereinafter, a surface emitting laser according to Modification 3 of the first embodiment of the present technology will be described.

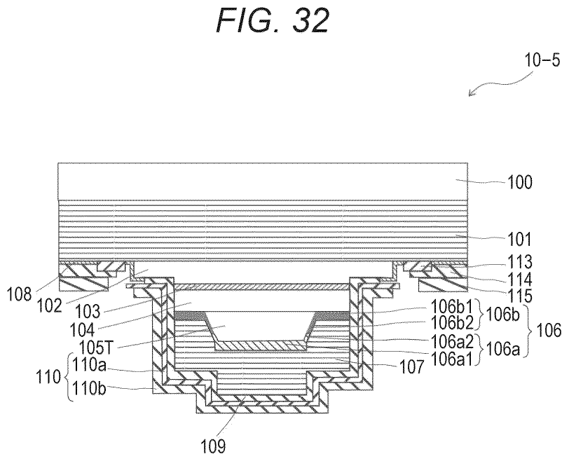

FIG. 32 is a cross-sectional view of a surface emitting laser 10-5 according to Modification 3 of the first embodiment.

The surface emitting laser 10-5 has a configuration similar to that of the surface emitting laser 10-1 according to Example 1 of the first embodiment except that it is a back surface emission type and has an intracavity structure.

In the surface emitting laser 10-5, the mesa structure is covered with a three-layer structure in which the anode electrode 109, the pad wiring 110a, and the plated wiring 110b are laminated, the cathode electrode 113 is provided in contact with the peripheral portion of the mesa structure of the first multilayer film reflector 101, and the pad wiring 114 and the plated wiring 115 are laminated in this order on the cathode electrode 113.

The surface emitting laser 10-5 performs an operation (however, the current path does not pass through the substrate 100, and light is emitted to the back surface side of the substrate 100) similar to the surface emitting laser 10-1 according to Example 1 of the first embodiment, is manufactured by substantially a similar manufacturing method, and has a similar effect.

### <10. Surface Emitting Laser According to Modification 4 of First Embodiment of Present Technology>

Hereinafter, a surface emitting laser according to Modification 4 of the first embodiment of the present technology will be described.

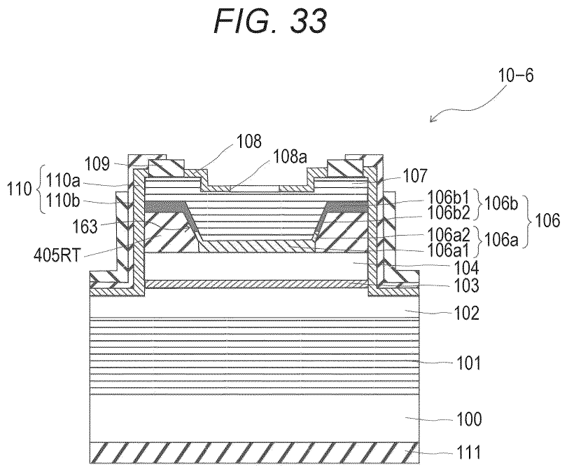

FIG. 33 is a cross-sectional view of a surface emitting laser 10-6 according to Modification 4 of the first embodiment.

The surface emitting laser 10-6 has substantially a configuration similar to that of the surface emitting laser 10-1 according to Example 1 of the first embodiment except that the semiconductor layer 405RT is recessed from the second multilayer film reflector 107 side to the active layer 103 side in a reverse tapered shape.

The semiconductor layer 405RT is constituted by, for example, an AlGaAs-based compound semiconductor. More specifically, the semiconductor layer 405RT has a graded layer configured such that the Al composition gradually increases from the top surface to the bottom surface between 0% and 35%, and an etching stop layer having an Al composition of 40% to 70% and located below the graded layer.

The thickness of the graded layer is, for example, about 30 nm to 100 nm.

The surface emitting laser 10-6 performs an operation similar to that of the surface emitting laser 10-1 according to Example 1 of the first embodiment.

### <<Method for Manufacturing Surface Emitting Laser>>

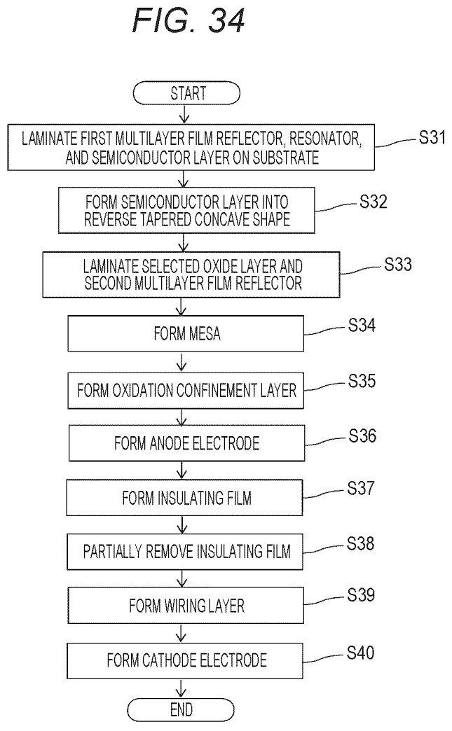

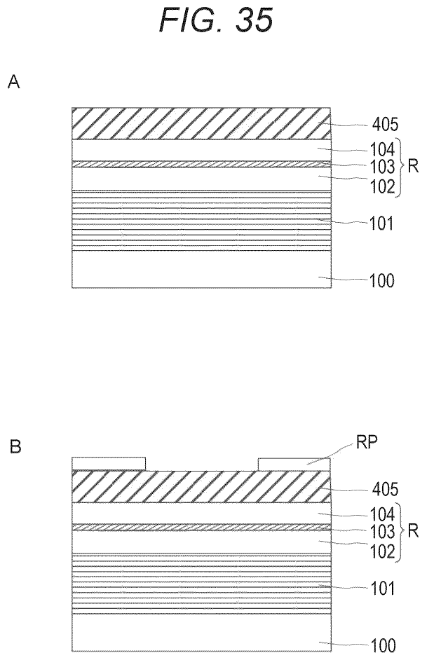

Hereinafter, a method for manufacturing the surface emitting laser 10-6 according to Modification 4 of the first embodiment of the present technology will be described with reference to the flowchart of FIG. 34 and the cross-sectional views of FIGS. 35A to 41B.

Here, as an example, a plurality of surface emitting lasers 10-6 is simultaneously generated on one wafer which is a base material of the substrate 100 by a semiconductor manufacturing method using a semiconductor manufacturing apparatus. Next, the plurality of continuous surface emitting lasers 10-6 is separated from each other by dicing to obtain a plurality of chip-shaped surface emitting lasers 10-6.

In the first step S31, the first multilayer film reflector 101, the resonator configuration portion R, and the semiconductor layer 405 are laminated on the substrate 100. Specifically, as illustrated in FIG. 35A, a first multilayer film reflector 101, a first cladding layer 102, an active layer 103, a second cladding layer 104, and a semiconductor layer 405 to be a semiconductor layer 405RT are laminated in this order on a substrate 100 by using a chemical vapor deposition (CVD) method, for example, a metal organic chemical vapor deposition (MOCVD) method.

The semiconductor layer 405 includes a graded layer (upper layer) and an etching stop layer (lower layer) similar to the semiconductor layer 405RT.

In the next step S32, the semiconductor layer 405 is formed into a reverse tapered concave shape.

Specifically, first, a resist pattern RP is formed on a position where the semiconductor layer 405RT of the semiconductor layer 405 is to be formed (see FIG. 35B). At this time, the resist pattern RP is formed such that the plan view shape is a polygon (for example, a regular hexagon) having no plane perpendicular to the direction.

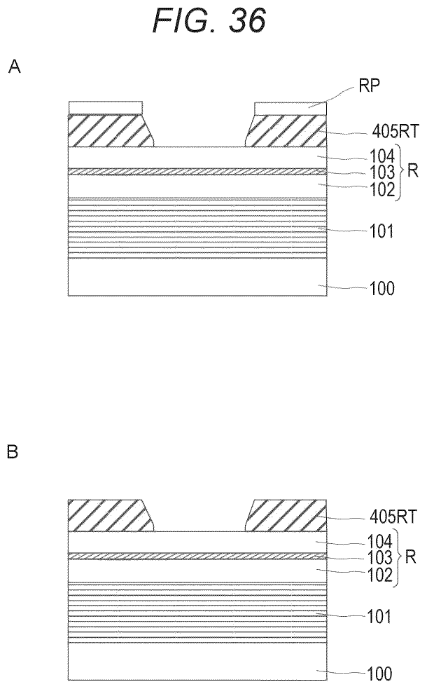

Next, using the resist pattern RP as a mask, the semiconductor layer 405 is etched (wet etching) by, for example, citric acid hydrogen peroxide or the like (see FIG. 36A). At this time, the etching rate of the semiconductor layer 405 changes according to the Al composition of AlGaAs. More specifically, in the semiconductor layer 405, as the etching of the graded layer progresses, the Al composition becomes higher, the etching becomes slower, and the etching stops in the etching stop layer. As a result, the semiconductor layer 405 is more greatly affected by the side etching in a region having a lower Al composition and is formed into a reverse tapered concave shape, and the semiconductor layer 405RT is generated.

Finally, the resist pattern RP is removed by acetone treatment or the like (see FIG. 36B). As a result, the semiconductor layer 405RT is exposed. The recess defined by the exposed semiconductor layer 405RT has a plan view shape of a polygon (for example, a regular hexagon) having no plane perpendicular to the direction.

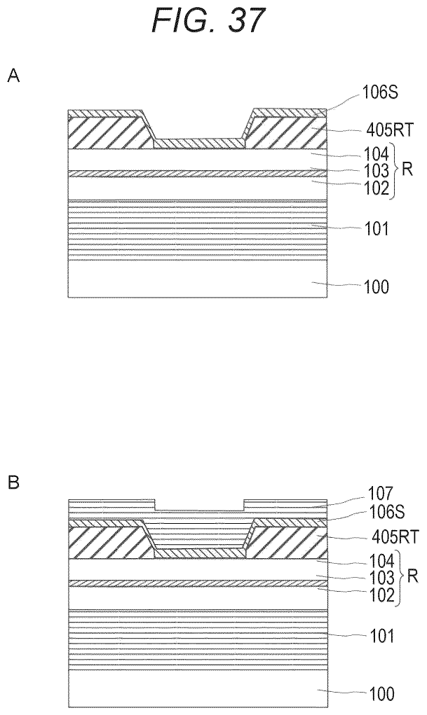

In the next step S33, the selected oxide layer 106S and the second multilayer film reflector 107 are laminated. Specifically, the selected oxide layer 106S and the second multilayer film reflector 107 are grown in this order on the resonator configuration portion R and the semiconductor layer 405RT by regrowth to generate a laminate (see FIGS. 37A and 37B). At this time, the selected oxide layer 106S and the second multilayer film reflector 107 are formed in a shape following the shape of the semiconductor layer 405RT. In particular, in the selected oxide layer 106S, a portion covering the side surface of the semiconductor layer 405RT is a thin film portion thinned over the entire circumference of the semiconductor layer 405RT.

In the next step S34, a mesa is formed.

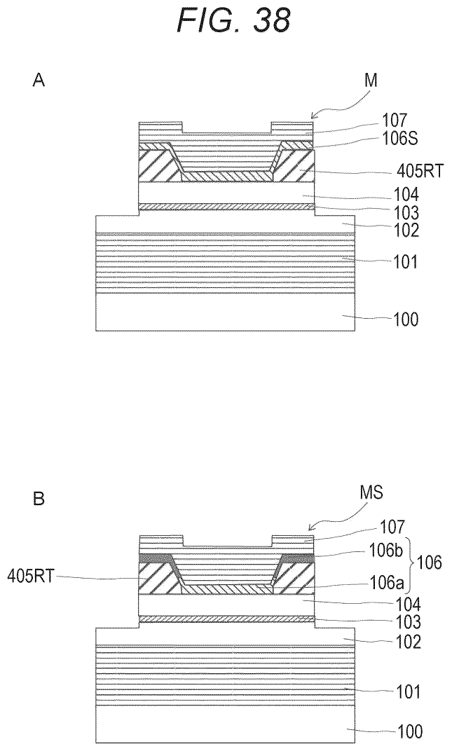

Specifically, first, a resist pattern for forming the mesa M having the mesa structure MS is generated on the second multilayer film reflector 107, and the laminate is etched by, for example, the RIE method using the resist pattern as a mask to form the mesa M (see FIG. 38A). Here, etching is performed until at least the side surface of the selected oxide layer 106S is exposed (for example, until the etching bottom surface is located in the first cladding layer 102). The mesa M is formed in a shape (for example, a regular hexagon) corresponding to the shape of the semiconductor layer 405RT, for example.

Finally, the resist pattern is removed by acetone treatment or the like.

In the next step S35, the oxidation confinement layer 106 is formed. Specifically, the selected oxide layer 106S of the mesa M (see FIG. 38A) is selectively oxidized to generate the oxidation confinement layer 106 (see FIG. 38B). More specifically, the mesa M is exposed to a water vapor atmosphere, and the selected oxide layer 106S is oxidized from the side surface (Al in AlAs is selectively oxidized). At this time, oxidation stops in the thin film portion of the selected oxide layer 106S. As a result, the oxidation confinement layer 106 including the non-oxidized region 106a and the oxidized region 106b is formed. As a result, the mesa M becomes the mesa structure MS.

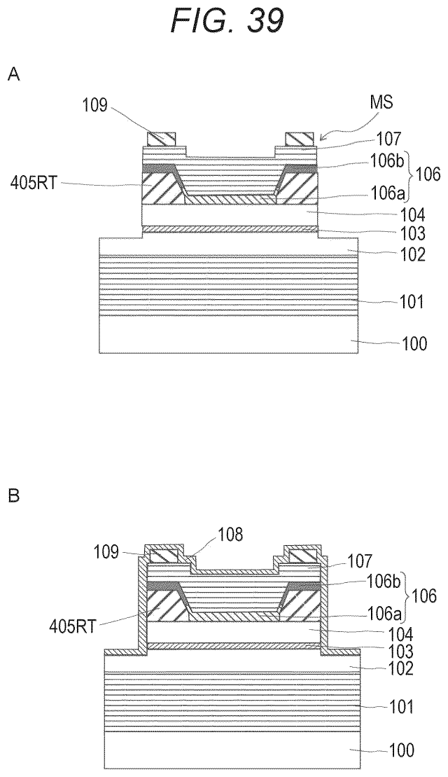

In the next step S36, the anode electrode 109 is formed (see FIG. 39A). Specifically, a film of the electrode material of the anode electrode 109 is formed on the peripheral portion of the top portion of the mesa structure MS (on the second multilayer film reflector 107) by a vapor deposition method, a sputtering method, or the like, and patterning is performed by a lift-off method, for example. At this time, the anode electrode 109 is formed in a shape (for example, a regular hexagonal frame shape) corresponding to the shape of the semiconductor layer 405RT, for example.

In the next step S37, the insulating film 108 is formed (see FIG. 39B). Specifically, the insulating film 108 is formed on the laminate on which the anode electrode 109 is formed by, for example, a vapor deposition method, a sputtering method, or the like.

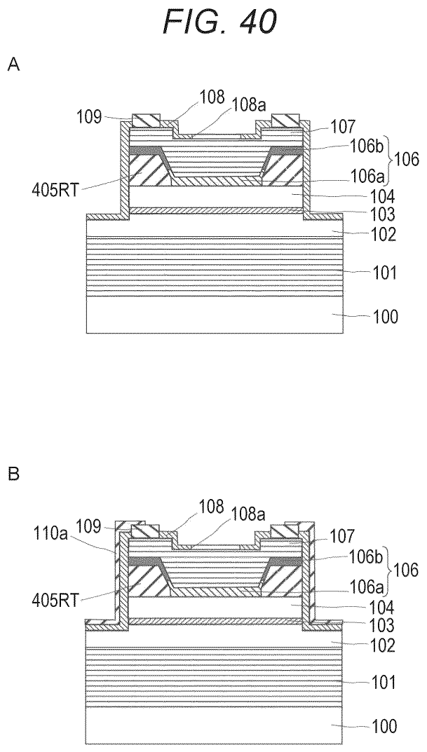

In the next step S38, the insulating film 108 is partially removed (see FIG. 40A). Specifically, the insulating film 108 covering the central portion of the top portion of the mesa structure MS and the insulating film 108 covering the anode electrode 109 are etched and removed. As a result, the emission port 108a is opened and the anode electrode 109 is exposed.

In the next step S39, the wiring layer 110 is formed.

Specifically, first, a wiring material of the pad wiring 110a is formed by, for example, a vapor deposition method, a sputtering method, or the like, and patterning is performed by, for example, a lift-off method (see FIG. 40B). At this time, the pad wiring 110a is patterned so that a part thereof is in contact with the anode electrode 109 and does not enter the inside of the anode electrode 109.

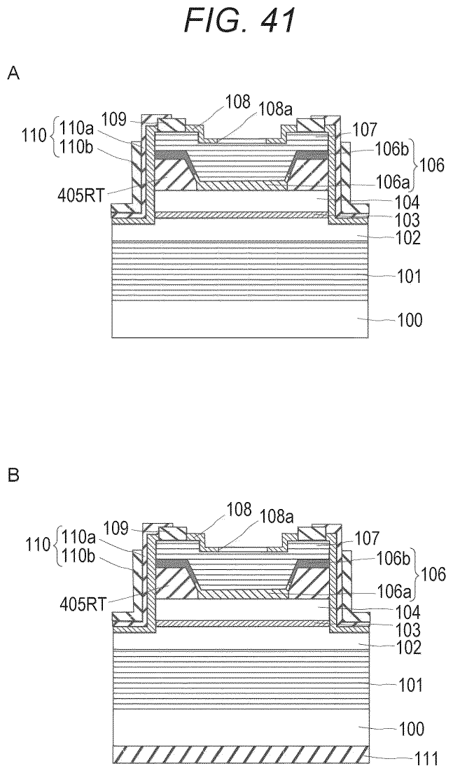

Next, a film of a wiring material of the plated wiring 110b is formed by, for example, a vapor deposition method, a sputtering method, or the like, and patterning is performed by, for example, a lift-off method (see FIG. 41A). At this time, the plated wiring 110b is patterned so as to be in contact with at least the pad wiring 110a.

In the final step S40, the cathode electrode 111 is formed (see FIG. 41B). Specifically, after the back surface of the substrate 100 is ground to be thinned, the electrode material of the cathode electrode 111 is solidly formed over substantially the entire region of the back surface of the substrate 100 by, for example, a vapor deposition method, a sputtering method, or the like.

Thereafter, processing such as annealing is performed to form a plurality of surface emitting lasers 10-6 on one wafer. Thereafter, the plurality of surface emitting lasers 10-6 is separated for each element by dicing to obtain a plurality of chip-shaped surface emitting lasers 10-6.

The surface emitting laser 10-6 has an effect similar to that of the surface emitting laser 10-1 according to Example 1 of the first embodiment.

### <11. Surface Emitting Laser According to Modification 5 of First Embodiment of Present Technology>

Hereinafter, a surface emitting laser according to Modification 5 of the first embodiment of the present technology will be described.

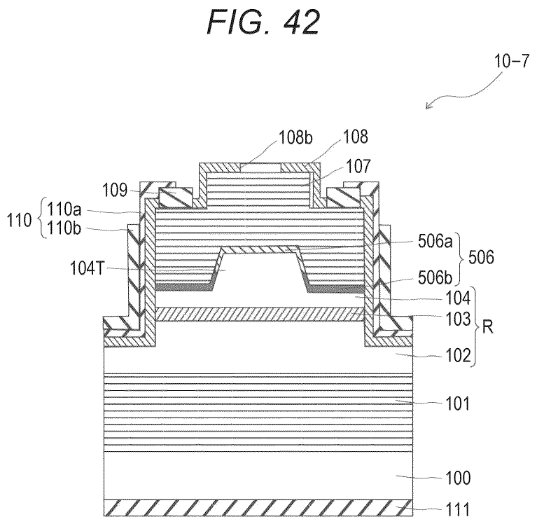

FIG. 42 is a cross-sectional view of a surface emitting laser 10-7 according to Modification 5 of the first embodiment.

As illustrated in FIG. 42, the surface emitting laser 10-7 has substantially a configuration similar to that of the surface emitting laser 10-1 according to Example 1 of the first embodiment except that the second cladding layer 104 has a protruding portion 104T protruding in a forward tapered shape from the active layer 103 side to the second multilayer film reflector 107 side and does not have the semiconductor layer 105T.

In the surface emitting laser 10-7, the oxidation confinement layer 506 including the non-oxidized region 506a and the oxidized region 506b covers the second cladding layer 104 from the second multilayer film reflector 107 side. The oxidation confinement layer 506 has a shape following the shape of the second cladding layer 104.

The surface emitting laser 10-7 performs an operation similar to that of the surface emitting laser 10-1 according to Example 1 of the first embodiment, is manufactured by substantially a similar manufacturing method, has a similar effect, and can simplify the layer configuration.

### <12. Surface Emitting Laser According to Modification 6 of First Embodiment of Present Technology>

Hereinafter, a surface emitting laser according to Modification 6 of the first embodiment of the present technology will be described.

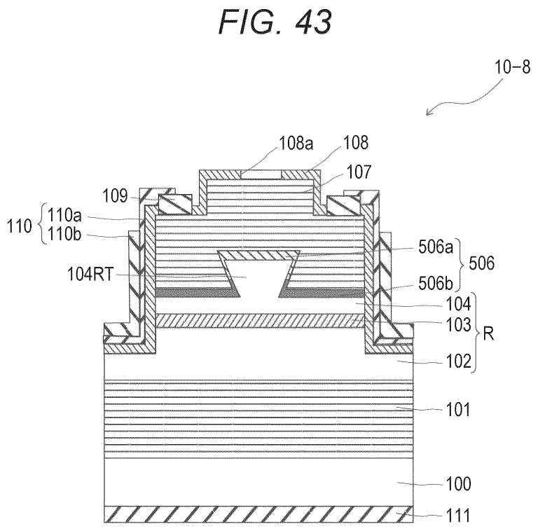

FIG. 43 is a cross-sectional view of a surface emitting laser 10-8 according to Modification 6 of the first embodiment.

As illustrated in FIG. 43, the surface emitting laser 10-8 has substantially a configuration similar to that of the surface emitting laser 10-2 according to Example 2 of the first embodiment except that the second cladding layer 104 has a protruding portion 104RT protruding in a reverse tapered shape from the active layer 103 side to the second multilayer film reflector 107 side and does not have the semiconductor layer 105T.

In the surface emitting laser 10-8, the oxidation confinement layer 506 including the non-oxidized region 506a and the oxidized region 506b covers the second cladding layer 104 from the second multilayer film reflector 107 side. The oxidation confinement layer 506 has a shape following the shape of the second cladding layer 104.

The surface emitting laser 10-8 performs an operation similar to that of the surface emitting laser 10-2 according to Example 2 of the first embodiment, is manufactured by a similar manufacturing method, has a similar effect, and can simplify the layer configuration.

### <13. Surface Emitting Laser According to Modification 7 of First Embodiment of Present Technology>

Hereinafter, a surface emitting laser according to Modification 7 of the first embodiment of the present technology will be described.

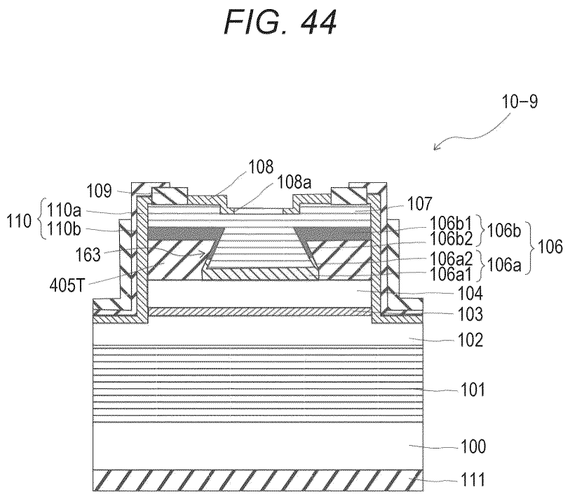

FIG. 44 is a cross-sectional view of a surface emitting laser 10-9 according to Modification 7 of the first embodiment.

As illustrated in FIG. 44, the surface emitting laser 10-9 has substantially a configuration similar to that of the surface emitting laser 10-6 according to Modification 4 of the first embodiment except that the semiconductor layer 405T is recessed in a tapered shape from the second multilayer film reflector 107 side to the active layer 103 side.

In the surface emitting laser 10-9, the semiconductor layer 405T does not have a surface perpendicular to the [0-11] direction (forward mesa direction), and as a result, the {111} A plane is not partially included in the slope of the step pattern.

The surface emitting laser 10-9 also performs an operation similar to that of the surface emitting laser 10-6 according to Modification 4 of the first embodiment, is manufactured by substantially a similar manufacturing method, and has a similar effect.

### <14. Surface Emitting Laser According to Modification 8 of First Embodiment of Present Technology>

Hereinafter, a surface emitting laser according to Modification 8 of the first embodiment of the present technology will be described.

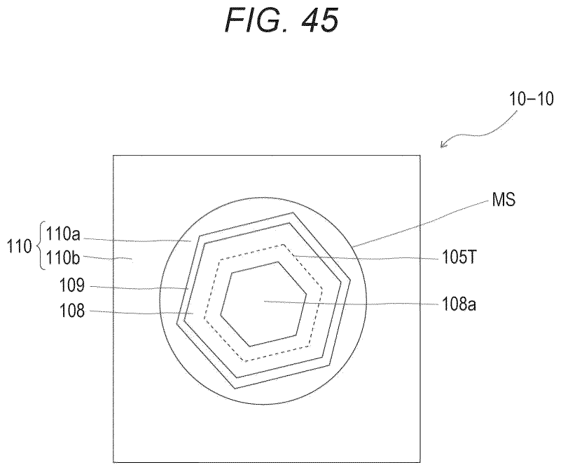

FIG. 45 is a plan view of a surface emitting laser 10-10 according to Modification 8 of the first embodiment.

The surface emitting laser 10-10 has a configuration similar to that of the surface emitting laser 10-1 according to Example 1 of the first embodiment except that the plan view shape of the mesa structure MS and the pad wiring 110a does not correspond to the plan view shape of the semiconductor layer 105T. Note that the plan view shape of the anode electrode 109 may not correspond to the plan view shape of the semiconductor layer 105T.

The surface emitting laser 10-10 also performs an operation similar to that of the surface emitting laser 10-1 according to Example 1 of the first embodiment, is manufactured by substantially a similar manufacturing method, and has a similar effect.

### <15. Surface Emitting Laser According to Modification of Second Embodiment of Present Technology>

Hereinafter, a surface emitting laser according to a modification of the second embodiment of the present technology will be described.

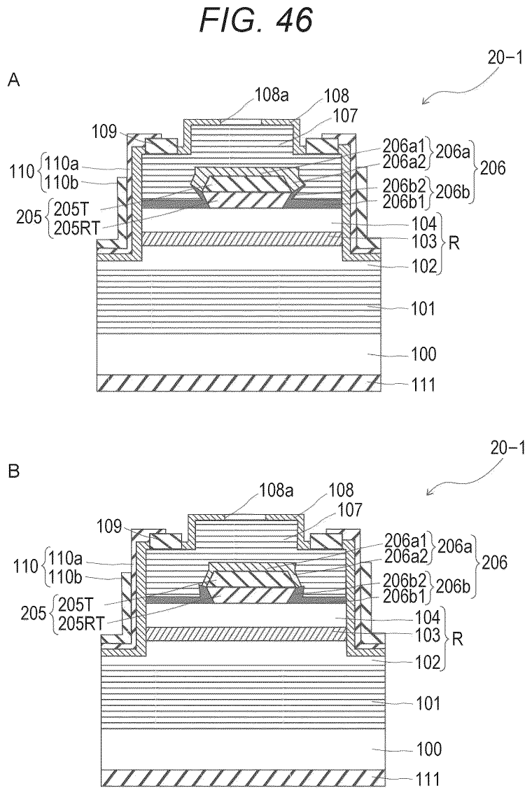

FIG. 46A is a cross-sectional view illustrating a cross section perpendicular to the direction (reverse mesa direction) of a surface emitting laser 20-1 according to a modification of the second embodiment. FIG. 46B is a cross-sectional view illustrating a cross section perpendicular to the [0-11] direction (forward mesa direction) of a surface emitting laser 20-1 according to a modification of the second embodiment.

As illustrated in FIGS. 46A and 46B, the surface emitting laser 20-1 according to the modification of the second embodiment has substantially a configuration similar to that of the surface emitting laser 20 of the second embodiment except that the semiconductor layer 205 has a forward tapered semiconductor layer 205T as an upper layer and a reverse tapered semiconductor layer 205RT as a lower layer.

The surface emitting laser 20 also performs an operation similar to that of the surface emitting laser 20-1 according to the second embodiment, is manufactured by substantially a similar manufacturing method, and has a similar effect.

### <16. Surface Emitting Laser According to Modification 1 of Third Embodiment of Present Technology>

Hereinafter, a surface emitting laser according to Modification 1 of the third embodiment of the present technology will be described.

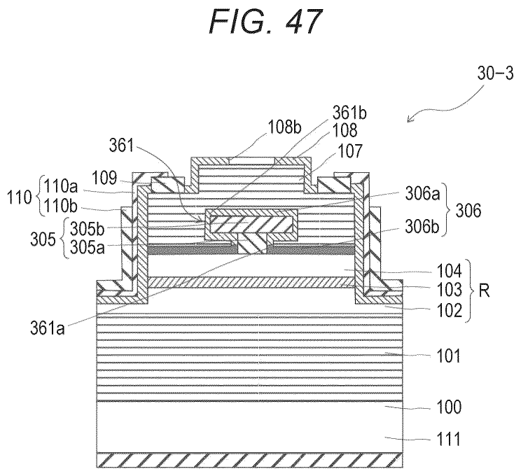

FIG. 47 is a cross-sectional view of a surface emitting laser 30-3 according to Modification 1 of the third embodiment.

As illustrated in FIG. 47, the surface emitting laser 30-3 has a configuration similar to that of the surface emitting laser 30-1 according to Example 1 of the third embodiment except that a boundary between the non-oxidized region 306a and the oxidized region 306b in the oxidation confinement layer 306 exists in the first portion 361a of the route-around portion 361.

The surface emitting laser 30-3 also performs an operation similar to that of the surface emitting laser 30-1 according to Example 1 of the third embodiment, is manufactured by substantially a similar manufacturing method, and has a similar effect.

### <17. Surface Emitting Laser According to Modification 2 of Third Embodiment of Present Technology>

Hereinafter, a surface emitting laser according to Modification 2 of the third embodiment of the present technology will be described.

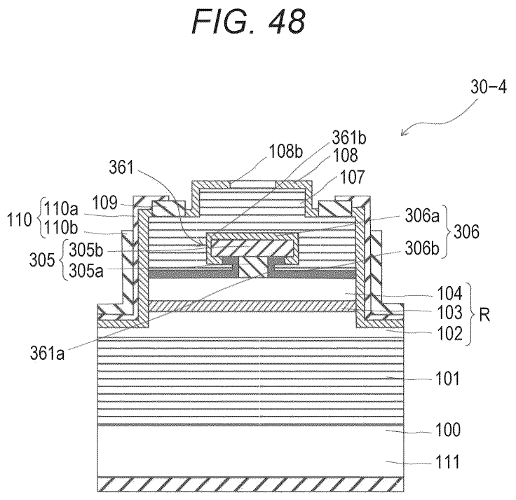

FIG. 48 is a cross-sectional view of a surface emitting laser 30-4 according to Modification 2 of the third embodiment.

As illustrated in FIG. 48, the surface emitting laser 30-4 has a configuration similar to that of the surface emitting laser 30-1 according to Example 1 of the third embodiment except that the boundary between the non-oxidized region 306a and the oxidized region 306b in the oxidation confinement layer 306 exists in a portion covering the lower surface of the overhang portion of the semiconductor layer 305 in the second portion 361b of the route-around portion 361.

The surface emitting laser 30-4 also performs an operation similar to that of the surface emitting laser 30-1 according to Example 1 of the third embodiment, is manufactured by substantially a similar manufacturing method, and has a similar effect.

### <18. Surface Emitting Laser According to Modification 3 of Third Embodiment of Present Technology>

Hereinafter, a surface emitting laser according to Modification 3 of the third embodiment of the present technology will be described.

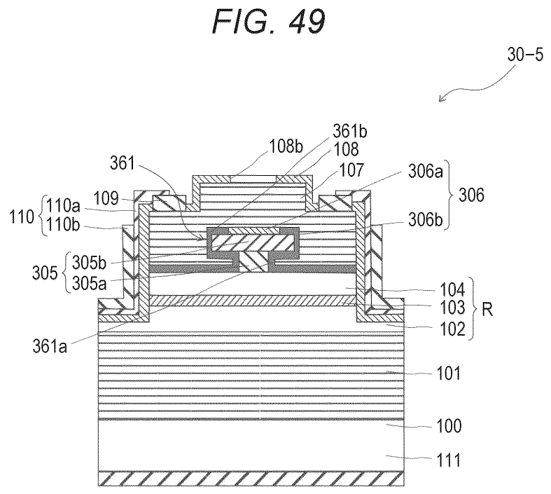

FIG. 49 is a cross-sectional view of a surface emitting laser 30-5 according to Modification 3 of the third embodiment.

As illustrated in FIG. 49, the surface emitting laser 30-5 has a configuration similar to that of the surface emitting laser 30-1 according to Example 1 of the third embodiment except that a boundary between the non-oxidized region 306a and the oxidized region 306b in the oxidation confinement layer 306 exists in a portion covering the upper surface of the overhang portion of the semiconductor layer 305 in the second portion 361b of the route-around portion 361.

More specifically, in the surface emitting laser 30-5, the non-oxidized region 306a exists in a position corresponding to at least the entire region of the semiconductor layer 305a (oxidation confinement diameter setting portion).

The surface emitting laser 30-5 also performs an operation similar to that of the surface emitting laser 30-1 according to Example 1 of the third embodiment, is manufactured by substantially a similar manufacturing method, and has a similar effect.

### <19. Surface Emitting Laser According to Modification 4 of Third Embodiment of Present Technology>

Hereinafter, a surface emitting laser according to Modification 4 of the third embodiment of the present technology will be described.

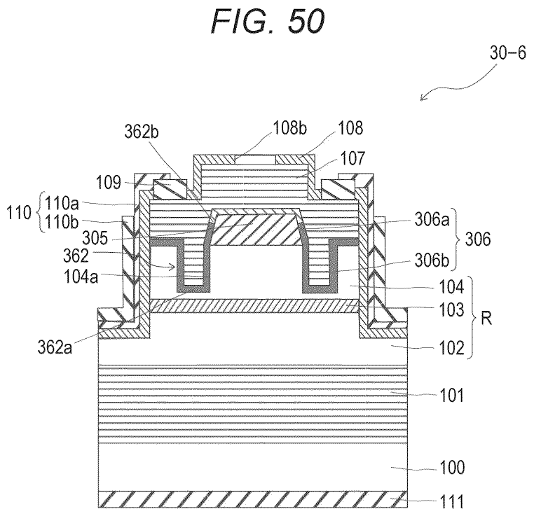

FIG. 50 is a cross-sectional view of a surface emitting laser 30-6 according to Modification 4 of the third embodiment.

As illustrated in FIG. 50, the surface emitting laser 30-6 has a configuration similar to that of the surface emitting laser 30-2 according to Example 2 of the third embodiment except that the boundary between the non-oxidized region 306a and the oxidized region 306b in the oxidation confinement layer 306 exists in a portion covering the side surface of the semiconductor layer 305 in the second portion 362b of the route-around portion 362.

The surface emitting laser 30-6 also performs an operation similar to that of the surface emitting laser 30-2 according to Example 2 of the third embodiment, is manufactured by substantially a similar manufacturing method, and has a similar effect.

### <20. Surface Emitting Laser According to Modification 5 of Third Embodiment of Present Technology>

Hereinafter, a surface emitting laser according to Modification 5 of the third embodiment of the present technology will be described.

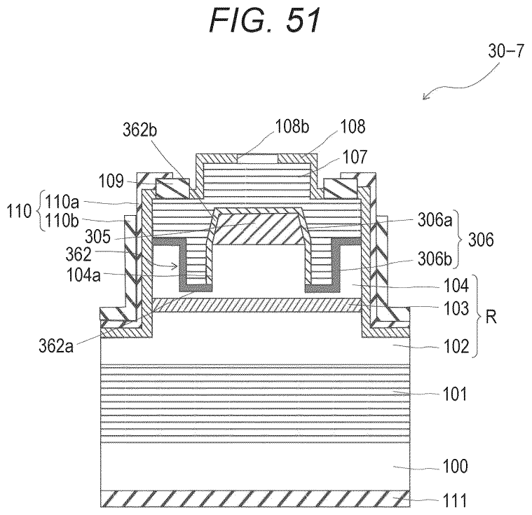

FIG. 51 is a cross-sectional view of a surface emitting laser 30-7 according to Modification 5 of the third embodiment.

As illustrated in FIG. 51, the surface emitting laser 30-7 has a configuration similar to that of the surface emitting laser 30-2 according to Example 2 of the third embodiment except that the boundary between the non-oxidized region 306a and the oxidized region 306b in the oxidation confinement layer 306 exists in a portion covering the boundary between the bottom surface and the side surface on the inner side of the groove 104a in the first portion 362a of the route-around portion 362.

The surface emitting laser 30-7 also performs an operation similar to that of the surface emitting laser 30-2 according to Example 2 of the third embodiment, is manufactured by substantially a similar manufacturing method, and has a similar effect.

### <21. Surface Emitting Laser According to Modification 6 of Third Embodiment of Present Technology>

Hereinafter, a surface emitting laser according to Modification 6 of the third embodiment of the present technology will be described.

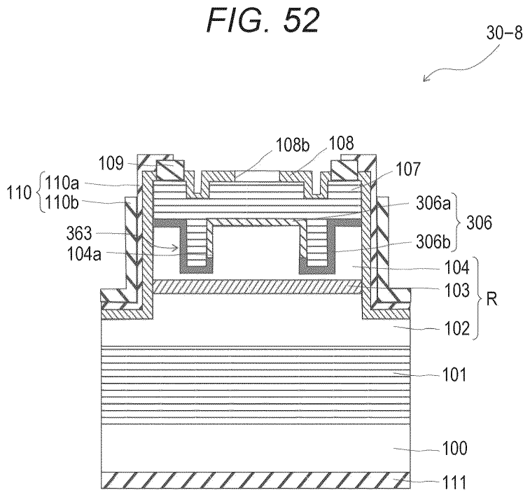

FIG. 52 is a cross-sectional view of a surface emitting laser 30-8 according to Modification 6 of the third embodiment.

As illustrated in FIG. 52, the surface emitting laser 30-8 has substantially a configuration similar to that of the surface emitting laser 30-2 according to Example 2 of the third embodiment except that the semiconductor layer 305 is not provided. Note that, also in the surface emitting laser 30-8, the boundary between the non-oxidized region 306a and the oxidized region 306b preferably exists in a portion covering the side surface on the inner side of the groove 104a in the route-around portion 363.

The surface emitting laser 30-8 also performs an operation similar to that of the surface emitting laser 30-2 according to Example 2 of the third embodiment, is manufactured by substantially a similar manufacturing method, has a similar effect, and can simplify the layer configuration.

### <22. Other Modifications of Present Technology>

The surface emitting laser according to the present technology is not limited to the configuration described in each of the above embodiments, examples, and modifications, and can be appropriately changed.

In each of the above embodiments, examples, and modifications, a GaAs substrate is used as the substrate 100, but a GaN substrate, an InP substrate, a Si substrate, or the like may be used. The surface emitting laser according to the present technology can be applied to any material system having an oscillation wavelength in the range of, for example, 200 nm to 2000 nm.

In each of the above embodiments, examples, and modifications, the first and second multilayer film reflectors 101 and 107 are constituted by a semiconductor, but may be constituted by, for example, a dielectric, a metal, or the like.

In each of the above embodiments, examples, and modifications, the wiring layer 110 has a two-layer structure including the pad wiring 110a and the plated wiring 110b, but may have a single-layer structure including one of the pad wiring 110a and the plated wiring 110b, or may have a three-layer or more-layer structure in which another at least one wiring is added.

In each of the above embodiments, examples, and modifications, a single surface emitting laser has been described as an example, but the surface emitting laser according to the present technology can also constitute a surface emitting laser array in which a plurality of the surface emitting lasers is two-dimensionally arranged.

In the surface emitting laser according to each of the above embodiments, examples, and modifications, a layer configuration in which conductivity types (n-type and p-type) are reversed may be adopted.

In each of the above embodiments, examples, and modifications, the thicknesses of the semiconductor layer and the second cladding layer 104 covered with the oxidation confinement layer are preferably, for example, in the range of 1 nm to 1 μm.

The cathode electrode 111 is a solid film, but may be patterned.

In each of the above embodiments, examples, and modifications, a contact layer for contact with an electrode may be provided on the second multilayer film reflector 107.

In each of the above embodiments, examples, and modifications, a buffer layer may be provided between the substrate 100 and the first multilayer film reflector 101.

Part of the configurations of the surface emitting lasers according to the above-described embodiments, examples, and modifications may be combined within a range not contradictory to each other.

In the above-described embodiments, examples, and modifications, the material, thickness, width, length, shape, size, arrangement, and the like of each component constituting the surface emitting laser can be appropriately changed within a range functioning as the surface emitting laser.

### <23. Application Example to Electronic Device>

The technology according to the present disclosure (the present technology) can be applied to various products (electronic devices). For example, the technology according to the present disclosure may be realized as an element mounted on any type of a mobile phone (including a smartphone), a wearable device, an automobile, an electric vehicle, a hybrid electric vehicle, a motorcycle, a bicycle, a personal mobility, an airplane, a drone, a ship, a robot, and the like.

The surface emitting laser according to the present technology can also be applied as, for example, a light source of a device that forms or displays an image by laser light (for example, a laser printer, a laser copier, a projector, a head mounted display, a head-up display, or the like).

<24. Example in which Surface Emitting Laser is Applied to Distance Measuring Device>

Hereinafter, application examples of the surface emitting laser according to each of the above-described embodiments, examples, and modifications will be described.

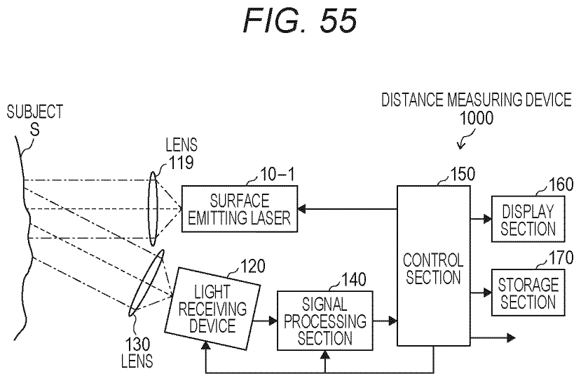

FIG. 55 illustrates an example of a schematic configuration of a distance measuring device 1000 including the surface emitting laser 10-1 as an example of an electronic device according to the present technology. The distance measuring device 1000 measures the distance to a subject S by a time of flight (TOF) method. The distance measuring device 1000 includes a surface emitting laser 10-1 as a light source. The distance measuring device 1000 includes, for example, the surface emitting laser 10-1, a light receiving device 120, lenses 119 and 130, a signal processing section 140, a control section 150, a display section 160, and a storage section 170.

The light receiving device 120 detects light reflected by the subject S. The lens 119 is a lens for collimating the light emitted from the surface emitting laser 10-1, and is a collimating lens. The lens 130 is a lens for condensing light reflected by the subject S and guiding the light to the light receiving device 120, and is a condenser lens.

The signal processing section 140 is a circuit for generating a signal corresponding to a difference between a signal input from the light receiving device 120 and a reference signal input from the control section 150. The control section 150 includes, for example, a time to digital converter (TDC). The reference signal may be a signal input from the control section 150, or may be an output signal of a detecting section that directly detects the output of the surface emitting laser 10-1. The control section 150 is, for example, a processor that controls the surface emitting laser 10-1, the light receiving device 120, the signal processing section 140, the display section 160, and the storage section 170. The control section 150 is a circuit that measures a distance to the subject S on the basis of a signal generated by the signal processing section 140. The control section 150 generates a video signal for displaying information about the distance to the subject S, and outputs the video signal to the display section 160. The display section 160 displays information about the distance to the subject S on the basis of the video signal input from the control section 150. The control section 150 stores information about the distance to the subject S in the storage section 170.

In the present application example, instead of the surface emitting laser 10-1, any one of the above-described surface emitting lasers 10-2, 10-3, 10-4, 10-5, 10-6, 10-7, 10-8, 10-9, 10-10, 20, 20-1, 30-1, 30-2, 30-3, 30-4, 30-5, 30-6, 30-7, and 30-8 can be applied to the distance measuring device 1000.

### <25. Example of Mounting Distance Measuring Device on Moving Body>

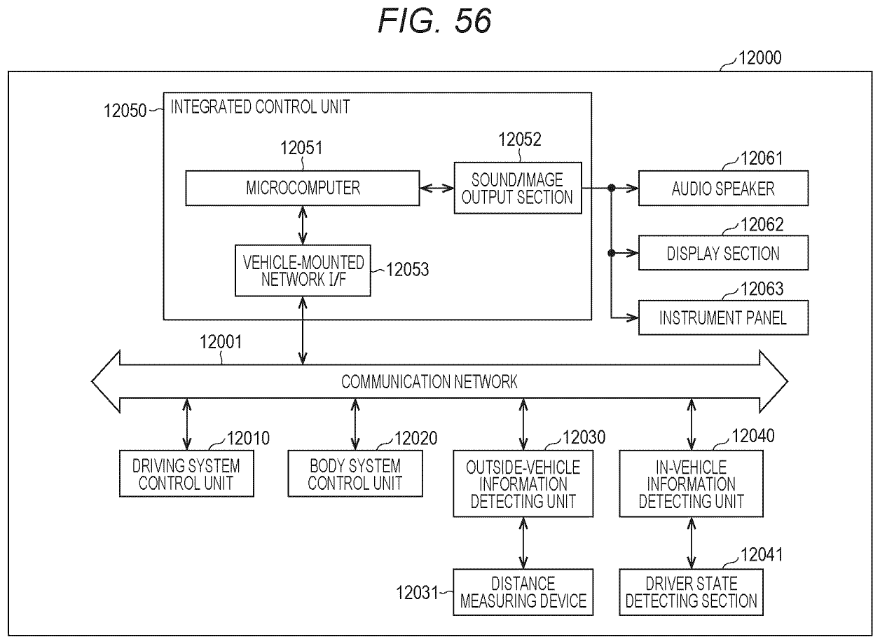

FIG. 56 is a block diagram illustrating a schematic configuration example of a vehicle control system which is an example of a moving body control system to which the technology according to the present disclosure can be applied.

The vehicle control system 12000 includes a plurality of electronic control units connected to each other via a communication network 12001. In the example depicted in FIG. 56, the vehicle control system 12000 includes a driving system control unit 12010, a body system control unit 12020, an outside-vehicle information detecting unit 12030, an in-vehicle information detecting unit 12040, and an integrated control unit 12050. Furthermore, a microcomputer 12051, a sound/image output section 12052, and a vehicle-mounted network interface (I/F) 12053 are illustrated as the functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information regarding the outside of the vehicle equipped with the vehicle control system 12000. For example, a distance measuring device 12031 is connected to the outside-vehicle information detecting unit 12030. The distance measuring device 12031 includes the above-described distance measuring device 1000. The outside-vehicle information detecting unit 12030 causes the distance measuring device 12031 to measure a distance to an object (subject S) outside the vehicle, and acquires distance data obtained by the measurement. The outside-vehicle information detecting unit 12030 may perform object detection processing of a person, a car, an obstacle, a sign, or the like on the basis of the acquired distance data.

The in-vehicle information detecting unit 12040 detects information about the inside of the vehicle. The in-vehicle information detecting unit 12040 is, for example, connected with a driver state detecting section that detects the state of a driver. The driver state detecting section 12041 may include, for example, a camera that images the driver, and, on the basis of detection information input from the driver state detecting section 12041, the in-vehicle information detecting unit 12040 may calculate a degree of fatigue or a degree of concentration of the driver, or may determine whether or not the driver is dozing off.

The microcomputer 12051 can calculate a control target value for the driving force generating device, the steering mechanism, or the braking device on the basis of the information about the inside or outside of the vehicle acquired by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS), the functions including collision avoidance or shock mitigation for the vehicle, follow-up traveling based on an inter-vehicle distance, vehicle speed maintaining traveling, vehicle collision warning, vehicle lane departure warning, and the like.

Furthermore, the microcomputer 12051 controls the driving force generating device, the steering mechanism, the braking device, or the like on the basis of the information around the vehicle acquired by the outside-vehicle information detecting unit 12030 or the in-vehicle information detecting unit 12040, thereby performing cooperative control for the purpose of automated driving or the like in which the vehicle automatedly travels without depending on the operation of the driver.

Further, the microcomputer 12051 can output a control command to the body system control unit 12020 on the basis of the information about the outside of the vehicle acquired by the outside-vehicle information detecting unit 12030. For example, the microcomputer can perform cooperative control for the purpose of preventing glare, such as switching from a high beam to a low beam, by controlling the headlamp according to the position of a preceding vehicle or an oncoming vehicle detected by the outside-vehicle information detecting unit 12030.

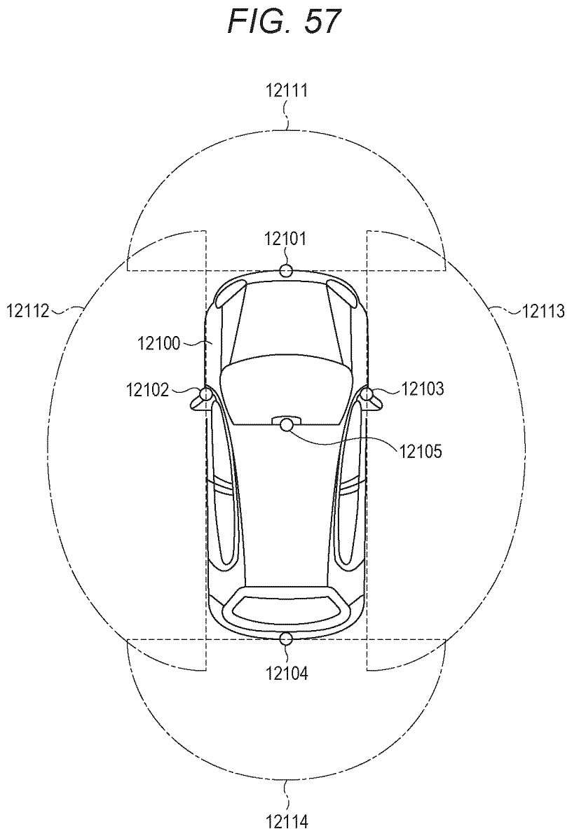

The sound/image output section 12052 transmits an output signal of at least one of a sound or an image to an output device capable of visually or auditorily notifying information to an occupant of the vehicle or the outside of the vehicle. In the example of FIG. 56, an audio speaker 12061, a display section 12062, and an instrument panel 12063 are depicted as the output device. The display section 12062 may, for example, include at least one of an on-board display or a head-up display. FIG. 57 is a diagram illustrating an example of an installation position of the distance measuring device 12031.

In FIG. 57, a vehicle 12100 includes distance measuring devices 12101, 12102, 12103, 12104, and 12105 as the distance measuring device 12031.

The distance measuring devices 12101, 12102, 12103, 12104, and 12105 are provided, for example, at positions such as a front nose, sideview mirrors, a rear bumper, a back door, and an upper portion of a windshield in a vehicle interior of the vehicle 12100. The distance measuring device 12101 provided on the front nose and the distance measuring device 12105 provided on the upper portion of the windshield in the vehicle cabin mainly acquire data of the front side of the vehicle 12100. The distance measuring devices 12102 and 12103 provided at the sideview mirrors mainly acquire data on the sides of the vehicle 12100. The distance measuring device 12104 provided on the rear bumper or the back door mainly acquires data behind the vehicle 12100. The data of the front acquired by the distance measuring devices 12101 and 12105 is mainly used for detecting a preceding vehicle, a pedestrian, an obstacle, a traffic light, a traffic sign, or the like.

Note that FIG. 57 illustrates an example of detection ranges of the distance measuring devices 12101 to 12104. A detection range 12111 indicates a detection range of the distance measuring device 12101 provided on the front nose, detection ranges 12112 and 12113 indicate detection ranges of the distance measuring devices 12102 and 12103 provided at the sideview mirrors, respectively, and a detection range 12114 indicates a detection range of the distance measuring device 12104 provided on the rear bumper or the back door.

For example, the microcomputer 12051 can determine a distance to each three-dimensional object within the detection ranges 12111 to 12114 and a temporal change in the distance (a relative speed with respect to the vehicle 12100) on the basis of the distance data obtained from the distance measuring devices 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Moreover, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, on the basis of the distance data obtained from the distance measuring devices 12101 to 12104, the microcomputer 12051 can classify three-dimensional object data regarding three-dimensional objects into two-wheeled vehicles, standard-sized vehicles, large-sized vehicles, pedestrians, and other three-dimensional objects such as utility poles, extract the three-dimensional object data, and use the three-dimensional object data for automatic avoidance of obstacles. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is higher than or equal to a set value and there is thus a possibility of collision, the microcomputer 12051 can outputs a warning to the driver via the audio speaker 12061 or the display section 12062 and perform forced deceleration or avoidance steering via the driving system control unit 12010 to perform driving assistance for collision avoidance.

An example of the moving body control system to which the technology according to the present disclosure can be applied has been described above. The technology according to the present disclosure can be applied to the distance measuring device 12031 among the configurations described above.

Furthermore, the present technology can also have the following configurations.

(1) A surface emitting laser including:
a first multilayer film reflector;
a second multilayer film reflector;
an active layer disposed between the first and second multilayer film reflectors; and
an oxidation confinement layer disposed between the second multilayer film reflector and the active layer and having a non-oxidized region and an oxidized region,
in which the oxidation confinement layer includes an oxidation adjustment structure.

(2) The surface emitting laser according to (1), further including a semiconductor layer protruding from a side of the active layer to a side of the second multilayer film reflector or recessed from the side of the second multilayer film reflector to the side of the active layer, in which the oxidation confinement layer covers the semiconductor layer from the side of the second multilayer film reflector, and the oxidation adjustment structure includes an oxidation progression suppressing portion.

(3) The surface emitting laser according to (2), in which the oxidation progression suppressing portion has a thin film portion and/or a cutoff portion.

(4) The surface emitting laser according to (2) or (3), in which the oxidation progression suppressing portion exists corresponding to an entire circumference of the non-oxidized region.

(5) The surface emitting laser according to any one of (2) to (4), in which the oxidation progression suppressing portion is provided on at least a part of a side surface of the semiconductor layer.

(6) The surface emitting laser according to any one of (2) to (5), in which a longitudinal cross section of the semiconductor layer is not rectangular.

(7) The surface emitting laser according to any one of (2) to (6), in which the semiconductor layer does not have a {111} A plane on a surface thereof.

(8) The surface emitting laser according to any one of (2) to (7), in which the semiconductor layer has a polygonal horizontal cross section.

(9) The surface emitting laser according to any one of (2) to (8) in which the oxidation confinement layer does not have a thick film portion.

(10) The surface emitting laser according to any one of (2) to (9), in which a boundary between the non-oxidized region and the oxidized region exists in the oxidation progress suppressing portion.

(11) The surface emitting laser according to any one of (2) to (10), in which the semiconductor layer has a forward tapered longitudinal cross section, and does not have a plane perpendicular to an arbitrary crystal orientation within an angle range of ±22.5° from a direction in a plane including a direction and a direction.

(12) The surface emitting laser according to any one of (2) to (10), the semiconductor layer has a reverse tapered longitudinal cross section, and does not have a plane perpendicular to an arbitrary crystal orientation within an angle range of ±22.5° from a [0-11] direction in a plane including a direction and a direction.

(13) The surface emitting laser according to (2), in which the oxidation confinement layer has a thin film portion and a thick film portion in a predetermined longitudinal cross section.

(14) The surface emitting laser according to (2) or (13), in which the semiconductor layer has a {111} A plane on a surface thereof, and a longitudinal cross section thereof has a forward tapered shape and a reverse tapered shape.

(15) The surface emitting laser according to (14), in which the oxidation confinement layer has a boundary between the non-oxidized region and the oxidized region at a position corresponding to a boundary between the forward tapered shape and the reverse tapered shape of the semiconductor layer.

(16) The surface emitting laser according to (1), in which the oxidation adjustment structure has a route-around portion.

(17) The surface emitting laser according to (16), in which a boundary between the non-oxidized region and the oxidized region exists in the route-around portion.

(18) The surface emitting laser according to (16) or (17), further including a semiconductor layer protruding from a side of the active layer to a side of the second multilayer film reflector or recessed from the side of the second multilayer film reflector to the side of the active layer, in which the oxidation confinement layer covers the semiconductor layer from the side of the second multilayer film reflector, and at least a part of the route-around portion extends along the semiconductor layer.

(19) The surface emitting laser according to (18), in which the semiconductor layer has an eaves shape.

(20) The surface emitting laser according to (18) or (19), in which the semiconductor layer includes an oxidation confinement diameter setting portion that sets an oxidation confinement diameter of the oxidation confinement layer, and an overhang portion that overhangs from the oxidation confinement diameter setting portion.

(21) The surface emitting laser according to (20), in which the route-around portion includes a first portion extending along the oxidation confinement diameter setting portion, and a second portion continuous with the first portion and extending along the overhang portion.

(22) The surface emitting laser according to (16), further including a semiconductor layer disposed between the second multilayer film reflector and the active layer, in which a groove is provided on a surface of the semiconductor layer on the side of the second multilayer film reflector, and at least a part of the route-around portion extends along the groove.

(23) The surface emitting laser according to (22), in which the semiconductor layer is a cladding layer disposed between the active layer and the second multilayer film reflector.

(24) The surface emitting laser according to (22), further including a cladding layer disposed between the active layer and the semiconductor layer, in which the groove is provided in the cladding layer.

(25) The surface emitting laser according to (24), in which the route-around portion includes a first portion extending along the groove and a second portion continuous with the first portion and extending along the semiconductor layer.

(26) The surface emitting laser according to any one of (1) to (25), in which the oxidized region is isotropically oxidized.

(27) A surface emitting laser array including a plurality of the surface emitting laser according to any one of (1) to (26).

(28) An electronic device including the surface emitting laser according to any one of (1) to (26).

(29) An electronic device including the surface emitting laser array according to (27).

### REFERENCE SIGNS LIST

10-1 to 10-10, 20, 20-1, 30-1 to 30-8 Surface emitting laser
100 Substrate
101 First multilayer film reflector
103 Active layer
104 Second cladding layer (semiconductor layer)
105T, 105RT, 205, 305, 405RT, 405T Semiconductor layer
106, 206, 306, 506 Oxidation confinement layer
106a, 206a, 306a, 506a Non-oxidized region
106b, 206b, 306b, 506b Oxidized region

1. A surface emitting laser comprising:
a first multilayer film reflector;
a second multilayer film reflector;
an active layer disposed between the first and second multilayer film reflectors; and
an oxidation confinement layer disposed between the second multilayer film reflector and the active layer and having a non-oxidized region and an oxidized region,
wherein the oxidation confinement layer includes an oxidation adjustment structure.

2. The surface emitting laser according to claim 1, further comprising
a semiconductor layer protruding from a side of the active layer to a side of the second multilayer film reflector or recessed from the side of the second multilayer film reflector to the side of the active layer,
wherein the oxidation confinement layer covers the semiconductor layer from the side of the second multilayer film reflector, and
the oxidation adjustment structure includes an oxidation progression suppressing portion.

3. The surface emitting laser according to claim 2, wherein the oxidation progression suppressing portion has a thin film portion and/or a cutoff portion.

4. The surface emitting laser according to claim 2, wherein the oxidation progression suppressing portion exists corresponding to an entire circumference of the non-oxidized region.

5. The surface emitting laser according to claim 2, wherein the oxidation progression suppressing portion is provided on at least a part of a side surface of the semiconductor layer.

6. The surface emitting laser according to claim 2, wherein a longitudinal cross section of the semiconductor layer is not rectangular.

7. The surface emitting laser according to claim 2, wherein the semiconductor layer does not have a {111} A plane on a surface thereof.

8. The surface emitting laser according to claim 7, wherein the semiconductor layer has a polygonal horizontal cross section.

9. The surface emitting laser according to claim 2, wherein the oxidation confinement layer does not have a thick film portion.

10. The surface emitting laser according to claim 2, wherein a boundary between the non-oxidized region and the oxidized region exists in the oxidation progress suppressing portion.

11. The surface emitting laser according to claim 2, wherein the semiconductor layer has a forward tapered longitudinal cross section, and does not have a plane perpendicular to an arbitrary crystal orientation within an angle range of ±22.5° from a direction in a plane including a direction and a direction.

12. The surface emitting laser according to claim 2, wherein the semiconductor layer has a reverse tapered longitudinal cross section, and does not have a plane perpendicular to an arbitrary crystal orientation within an angle range of ±22.5° from a [0-11] direction in a plane including a direction and a direction.

13. The surface emitting laser according to claim 2, wherein the oxidation confinement layer has a thin film portion and a thick film portion in a predetermined longitudinal cross section.

14. The surface emitting laser according to claim 2, wherein the semiconductor layer has a {111} A plane on a surface thereof, and a longitudinal cross section thereof has a forward tapered shape and a reverse tapered shape.

15. The surface emitting laser according to claim 14, wherein the oxidation confinement layer has a boundary between the non-oxidized region and the oxidized region at a position corresponding to a boundary between the forward tapered shape and the reverse tapered shape of the semiconductor layer.

16. The surface emitting laser according to claim 1, wherein the oxidation adjustment structure has a route-around portion.

17. The surface emitting laser according to claim 16, wherein a boundary between the non-oxidized region and the oxidized region exists in the route-around portion.

18. The surface emitting laser according to claim 16, further comprising
a semiconductor layer protruding from a side of the active layer to a side of the second multilayer film reflector or recessed from the side of the second multilayer film reflector to the side of the active layer,
wherein the oxidation confinement layer covers the semiconductor layer from the side of the second multilayer film reflector, and
at least a part of the route-around portion extends along the semiconductor layer.

19. The surface emitting laser according to claim 18, wherein the semiconductor layer has an eaves shape.

20. The surface emitting laser according to claim 16, further comprising
a semiconductor layer disposed between the second multilayer film reflector and the active layer,
wherein a groove is provided on a surface of the semiconductor layer on the side of the second multilayer film reflector, and
at least a part of the route-around portion extends along the groove.
